(19) United States
(12) Patent Application Publication
(10) Pub. No.: US 2026/0114244 A1
(43) Pub. Date: Apr. 23, 2026

(54) METHODS OF FORMING SEMICONDUCTOR STRUCTURES

(71) Applicant: Semiconductor Manufacturing International (Shanghai) Corporation, Shanghai (CN)

(72) Inventor: Jisong JIN, Shanghai (CN)

(21) Appl. No.: 19/359,207

(22) Filed: Oct. 15, 2025

(30) Foreign Application Priority Data
Oct. 18, 2024 (CN) 202411466033.5

(51) Int. Cl. H01L 21/033; H01L 21/311

(52) U.S. Cl. CPC H10P 76/4085; H10P 50/283; H10P 50/73

(57) ABSTRACT

A method for forming semiconductor structures includes providing a base including a first area and a second area; modifying a portion of a second core material layer in the second area and forming a third core material layer having an etch selectivity with respect to the second core material layer; forming a first core material layer; patterning the first core material layer to form first core layers; forming first spacers; patterning the second and third core material layers to form second and third core layers; forming second spacers; and using the second spacers and the third core layers as a mask to pattern a target material layer, and forming first and second target structures. A pitch between adjacent first target structures is smaller than or equal to a pitch between adjacent second target structures. It enables simultaneous implementation of SAQP and SALELE processes and improves design freedom in patterning processes.

### CROSS-REFERENCE TO RELATED APPLICATION

This application claims the priority of Chinese Patent Application No. 202411466033.5, filed on October 18, 2024, the content of which is incorporated herein by reference in its entirety.

### TECHNICAL FIELD

The present disclosure generally relates to the field of semiconductor manufacturing and, more particularly, relates to a method of forming a semiconductor structure.

### BACKGROUND

With the rapid advance of semiconductor manufacturing technologies, semiconductor devices are developing towards higher component density and higher integration. Photolithography technology is a commonly used patterning method and the most critical production technology in semiconductor manufacturing processes. Along with continuous reduction of pattern critical dimension (CD) and pitch, self-aligned double patterning (SADP) can no longer meet current process requirements, and self-aligned quadruple patterning (SAQP) method comes into being. Generally, the minimum pitch that SADP can form with the deep ultraviolet (DUV) technology is about half of the pitch limit of 76 nm for a single DUV exposure, which is a pitch of 38 nm. As such, the limit of SAQP with the DUV technology is a pitch of 19 nm. When a good yield is ensured, the general SADP limit is around 40 nm, and the SAQP limit is around 24 nm. In the back-end process, the SADP or SAQP process is often not used to form metal patterns, while self-aligned litho-etch litho-etch or spacer assisted litho-etch litho-etch (SALELE) is often used. SALELE has the advantage of more design freedom than SADP, but the metal pitch limit is similar to SADP, and the minimum pitch can only be about 40 nm.

However, as the size of transistors and chips shrinks, the back-end metal pitch also needs to reach a value of smaller than 40 nm to 30 nm or even a smaller pitch. The traditional SAQP method can achieve smaller pitches, but like SADP, it has major limitations in metal line layout design. Metal line layout generally needs to take into account both smaller pitches and large pitches on the same chip, as well as design freedom such as freely placed metal line positions, which is difficult to achieve using purely the SAQP process. However, in the absence of extreme ultraviolet (EUV) exposure processing, it is relatively difficult to achieve both pitch reduction and design freedom through the SAQP process that only uses the DUV lithography. It also has great limitations on production of chips with more advanced processes.

In the 2015 SPIE conference paper “Impact of a SADP flow on the design and process for N10/N7 Metal” doi: 10.1117/12.2085923, harms caused by redundant metal lines and methods of removing them in an SADP process are elaborated in detail. However, the paper primarily uses additional masks to remove the extra metal lines, as shown in FIG. 35. A target structure with redundant metal lines removed is shown in part (a) of FIG. 35. However, with only a cut process, the paper retains all redundant metal lines in the final structure, as shown in part (b) of FIG. 35. Therefore, it is known that processes similar to SADP and SAQP, while capable of forming dense patterns, often result in the most tightly packed arrangements, meaning many redundant metal lines will exist. These metal lines do not participate in transistor interconnecting, but are difficult to remove without adding masks. It affects the capacitance between adjacent metal lines used for interconnects.

The disclosed structures and methods are directed to at least partially alleviating one or more problems set forth above and to solving other problems in the art.

### SUMMARY

One aspect of the present disclosure provides a method for forming a semiconductor structure. The method includes providing a base, wherein the base includes a substrate and a target material layer on the substrate, a second core material layer is formed over the base, the base further includes a first area for forming first target structures and a second area for forming second target structures, both the first target structure and the second target structure extend along a first direction, and a pitch between adjacent first target structures is smaller than or equal to a pitch between adjacent second target structures; forming first protective layers on the second core material layer, wherein a part of the first protective layers in the second area are separately disposed; performing a modification treatment on the second core material layer exposed in the second area using the first protective layers as a mask and forming a third core material layer having an etch selectivity with respect to a remaining portion of the second core material layer, wherein the remaining portion of the second core material layer is separate in the second area and surrounded by the third core material layer in the second area; removing the first protective layers; forming a first core material layer covering the second core material layer and the third core material layer; patterning the first core material layer and forming first core layers being separate in the first area, wherein the first core layers extend along the first direction and are arranged parallel to each other along a second direction, the first direction is perpendicular to the second direction; forming first spacers covering sidewalls of the first core layers; removing the first core layers; forming a second protective layer on the second core material layer and the third core material layer in the second area, wherein second protective layer openings are formed in the second protective layer, the second protective layer openings are separate, extend along the first direction, and are arranged parallel to each other along the second direction, and the second protective layer openings expose the third core material layer; patterning the second core material layer and the third core material layer using the first spacers and the second protective layer as a mask and forming second core layers corresponding to the second core material layer and third core layers corresponding to the third core material layer; removing the first spacers and the second protective layer; forming second spacers covering sidewalls of the second core layers and the third core layers; removing the second core layers; and patterning the target material layer using the second spacers and the third core layers as a mask and forming the first target structures in the first area and the second target structures in the second area.

Other aspects or embodiments of the present disclosure can be understood by those skilled in the art in light of the description, the claims, and the drawings of the present disclosure.

### BRIEF DESCRIPTION OF THE DRAWINGS

The following drawings are merely examples for illustrative purposes according to various disclosed embodiments and are not intended to limit the scope of the present disclosure.

FIGS. 1 to 34 illustrate schematic structural diagrams corresponding to steps in methods for forming a semiconductor structure according to various disclosed embodiments of the present disclosure.

FIG. 35 is a schematic diagram comparing target structures of two semiconductor structures.

### DETAILED DESCRIPTION

Reference will now be made in detail to exemplary embodiments of the disclosure, which are illustrated in the accompanying drawings. Wherever possible, the same reference numbers will be used throughout the drawings to refer to the same or like parts.

Embodiments of the present disclosure provide a method of forming a semiconductor structure. The method improves design freedom in patterning processes. At the same time, redundant first target structures in the first area may be removed.

The method includes providing a base, wherein the base includes a substrate and a target material layer on the substrate, a second core material layer is formed on the base, the base includes a first area for forming first target structures and a second area for forming second target structures, the first target structure and the second target structure both extend along a first direction, and a pitch between adjacent first target structures is smaller than or equal to a pitch between adjacent second target structures; forming first protective layers over the second core material layer, wherein the first protective layers in the second area are separately arranged; performing a modification treatment on the second core material layer exposed in the second area using the first protective layer as a mask, and forming a third core material layer having an etch selectivity with the remaining second core material layers, wherein the remaining second core material layers are separate in the second area and surrounded by the third core material layer in the second area; removing the first protective layer; forming a first core material layer covering the second core material layers and the third core material layer; patterning the first core material layer and forming separate first core layers in the first area, wherein the first core layers extend along a first direction and are arranged in parallel along a second direction, and the first direction is perpendicular to the second direction; forming first spacers covering sidewalls of the first core layers; removing the first core layers; forming a second protective layer on the second core material layers and the third core material layer in the second area, wherein separate second protective layer openings extending along the first direction and arranged in parallel along the second direction are formed in the second protective layer, and the second protective layer openings expose the third core material layer; patterning the second core material layer and the third core material layer using the first spacers and the second protective layers as a mask, and forming second core layers corresponding to the second core material layers and third core layers corresponding to the third core material layer; removing the first spacers and the second protective layers; forming the second spacers covering sidewalls of the second core layers and the third core layers; removing the second core layers; and patterning the target material layer using the second spacers and the third core layers as a mask, and forming the first target structures in the first area and the second target structures in the second area.

Compared with the prior art, the technical solution of embodiments of the present disclosure has the following advantages:

In the formation method provided by embodiments of the present disclosure, the base includes the first area for forming the first target structures and the second area for forming the second target structures. The pitch between adjacent first target structures is smaller than or equal to the pitch between adjacent second target structures. The target material layer is patterned using the second spacers and third core layers as a mask to form the first target structures in the first area and the second target structures in the second area. In some embodiments, for the first area, the first spacers covering sidewalls of the first core layers are formed. The second core material layers in the first area are patterned using the first spacers as a mask to form the separate second core layers in the first area. The second spacers covering sidewalls of the second core layers are formed. The target material layer is patterned using the second spacers as a mask, which adopts an SAQP process. The SAQP process may form first target structures with a smaller pitch. For the second area, a modification treatment is performed on a portion of the second core material layers in the second area to transform the portion of the second core material layers into the third core material layer having an etch selectivity with the second core material layer. The second core material layers and the third core material layer in the second area are patterned using the second protective layer to form the second core layers corresponding to the second core material layers and the third core layers corresponding to the third core material layer. The second spacers covering sidewalls of the second core layers and the third core layers are formed. The target material layer is patterned using the second spacers and the third core layers as a mask, which adopts an SALELE process capable of forming the second target structures with a larger pitch. That is, embodiments of the present disclosure may effectively integrate the SAQP process and the SALELE process, enabling formation of both the first target structures with a smaller pitch and the second target structures with a larger pitch on the same base. It facilitates meeting more semiconductor process requirements through process integration and improves design freedom in patterning processes.

Optionally, in the step of forming the first protective layer on the second core material layer, first openings exposing the second core material layer are also formed in the first protective layer in the first area. The first openings extend along the first direction. In the step of performing the modification treatment on the second core material layer exposed in the second area using the first protective layer as a mask, the modification treatment is also performed on the second core material layer exposed by the first openings in the first area to form the third core material layer in the first area. In the step of patterning the second core material layer and the third core material layer using the first spacers and the second protective layers as a mask, the third core material layer in the first area is also patterned using the first spacers to form the third core layers. In the first area, the second core layers and the third core layers corresponding to portions of the first spacers are alternately distributed along the first direction. In some embodiments, the third core material layer is also formed in the first area. Then the third core material layer in the first area is patterned to form the third core layers in the first area. When the target material layer is subsequently patterned using the second spacers and the third core layers as a mask, the target material layer corresponding to the third core layers in the first area is retained to block formation of some first target structures. Therefore, in some embodiments, some redundant first target structures in the first area made through the SAQP process may be removed without adding masks and process steps.

Optionally, in the step of forming the first protective layer on the second core material layer, second openings exposing the second core material layer are also formed in the first protective layer in the first area. The second openings extend along the first direction. In the step of performing the modification treatment on the second core material layer exposed in the second area using the first protective layer as a mask, the modification treatment is also performed on the second core material layer exposed by the second openings in the first area to form the third core material layer located in the first area. In the step of forming the second protective layers over the second core material layer and the third core material layer in the second area, the second protective layer is formed over the third core material layer in the first area. In the step of patterning the second core material layer and the third core material layer using the first spacers and the second protective layers as a mask, the third core material layer under the second protective layer in the first area is retained as the third core layers. In some embodiments, the third core material layer is also formed in the first area, and the second protective layer is used to protect the third core material layer in the first area. In the step of patterning the second core material layer and the third core material layer using the first spacers and the second protective layers as a mask, the third core material layer in the first area is retained as the third core layers in the first area. When the target material layer is subsequently patterned using the second spacers and the third core layers as a mask, the target material layer corresponding to the third core layers in the first area is retained to block formation of some first target structures. Therefore, in some embodiments, some redundant first target structures in the first area made with an SAQP process may be removed without adding masks and process steps.

As mentioned in the background section, the SALELE process is a common solution in back-end patterning. The process has two core values in patterning. The first value is the spacing between metal lines defined by two lithographies is determined by the thickness of the spacer during the process. The spacer is usually formed by an atomic layer deposition (ALD) process with very high uniformity. As such, the overlay of two lithographies does not cause a change of spacing between two adjacent metal lines. It also makes the spacing between metal lines very uniform and fixed, and opens a large process window for reliability tests such as time dependent dielectric breakdown (TDDB) and breakdown voltage (VBD). The second value is that the tip to tip of the metal lines defined by two lithographies may be formed very small by using cuts of patterning produced by other masks. Further, a cut corresponding to the first lithography and a cut corresponding to the second lithography may not interfere with each other. This is also called a self-aligned block process in the industry.

The above two advantages are the reason that SALELE not only balances the process difficulty at the back-end patterning, but also provides great design freedom. The SALELE process also has various similar solutions, such as that shown in CN111640668B and process solutions disclosed in US10991596B2.

In general, the minimum pitch created by immersion DUV (ArFi) in a single photolithography is about 80 nm. Thus, SALELE may use DUV equipment to achieve a minimum pitch of 38 nm to 40 nm, while more advanced chips require smaller pitches, such as 32 nm, 28 nm, 24 nm, etc.

With the traditional fin patterning, when a pitch reaches about 30 nm, the SAQP process may be used. Because SADP may only make a fin pattern with a minimum pitch of 38 nm, SADP needs to be repeated to become SAQP. The SAQP process may well meet the needs of fin patterning. Because fin patterns are relatively regular, the fin pitches in an area of a chip are generally fixed and regular, and the difference between areas is not very large. However, the SAQP solution has great limitations in the back-end process where metal lines have a high degree of freedom. For example, when metal patterns of SRAM are formed, metal lines formed by patterning are difficult to match patterns of the first metal layer of the traditional SRAM. Further, the width of metal lines formed by SAQP is relatively fixed, which also makes designs of other bypass circuits more difficult.

As such, currently for back-end patterning in semiconductor structures of the same area, it is difficult to achieve both smaller pitch and design freedom, meet more requirements of semiconductor processes, and improve design freedom in patterning processes correspondingly. The traditional SAQP process is difficult to remove redundant metal lines without adding a mask, which means that the SAQP process can often form the densest metal line arrangement. The spacing between densely packed metal lines is fixed and is determined by the second sidewall in the SAQP process. However, metal winding often needs to consider not only providing a smaller metal pitch, but also a smaller capacitance within the metal line layer. In the 2015 SPIE conference paper “Impact of a SADP flow on the design and process for N10/N7 Metal” doi: 10.1117/12.2085923, harms caused by redundant metal lines and methods of removing them in an SADP process are elaborated in detail. However, the paper primarily uses additional masks to remove excess metal lines, as shown in FIG. 35. A target structure with redundant metal lines removed is shown in part (a) of FIG. 35. However, in this paper, when only the cutting process is used, the redundant metal lines can only be retained in the final structure as shown in part (b) of FIG. 35.

In order to solve the above technical problems, embodiments of the present disclosure provide a formation method to make semiconductor structures. The method includes providing a base, wherein the base includes a substrate and a target material layer on the substrate, a second core material layer is formed over the base, the base further includes a first area for forming first target structures and a second area for forming second target structures, the first target structures and the second target structures each extend along a first direction, and a pitch between adjacent first target structures is smaller than or equal to a pitch between adjacent second target structures; forming first protective layers on the second core material layer, and the first protective layers located in the second area are separately arranged; performing a modification treatment on the second core material layer exposed in the second area using the first protective layers as a mask, and forming a third core material layer having an etch selectivity with the remaining second core material layers, wherein the remaining second core material layers are separate in the second area and surrounded by the third core material layer in the second area; removing the first protective layers; forming a first core material layer covering the second core material layer and the third core material layer; patterning the first core material layer to form separate first core layers in the first area, the first core layers extend along the first direction and are arranged in parallel along a second direction, and the first direction is perpendicular to the second direction; forming first spacers covering sidewalls of the first core layers; removing the first core layers; forming a second protective layer on the second core material layer and the third core material layer in the second area, wherein separate second protective layer openings extending along the first direction and arranged in parallel along the second direction are formed in the second protective layer, and the second protective layer openings expose the third core material layer; patterning the second core material layer and the third core material layer using the first spacers and the second protective layers as a mask, and forming second core layers corresponding to the second core material layer and third core layers corresponding to the third core material layer; removing the first spacers and the second protective layers; forming second spacers covering sidewalls of the second core layers and the third core layers; removing the second core layers; and patterning the target material layer using the second spacers and the third core layers as a mask, and forming the first target structures located in the first area and the second target structures located in the second area.

In some embodiments, for the first area, the first spacers covering sidewalls of the first core layers are formed. The second core material layer in the first area is patterned using the first spacers as a mask to form the separate second core layers in the first area. The second spacers covering sidewalls of the second core layers are formed. The target material layer is patterned using the second spacers as a mask, which adopts an SAQP process. The SAQP process may form first target structures with a smaller pitch. For the second area, a modification treatment is performed on a portion of the second core material layer in the second area to transform the portion of the second core material layer into the third core material layer having an etch selectivity with the second core material layer. The second core material layer and third core material layer in the second area are patterned using the second protective layers to form the second core layers corresponding to the second core material layer and the third core layers corresponding to the third core material layer. The second spacers are formed to cover sidewalls of the second core layers and the third core layers. The second spacers and the third core layers are used as a mask to pattern the target material layer, which adopts an SALELE process to make the second target structures. The second target structures with a larger pitch may be made using the SALELE process. Thus, embodiments of the present disclosure may better integrate the SAQP process and SALELE process. Both the first target structures with a smaller pitch and the second target structures with a larger pitch may be formed over the same base. It is conducive to meeting more semiconductor process needs and improving the design freedom in patterning processes through process integration.

In order to make the above objects, features, and advantages of the present disclosure more obvious and understandable, specific embodiments of the present disclosure will be described in detail below in conjunction with the accompanying drawings.

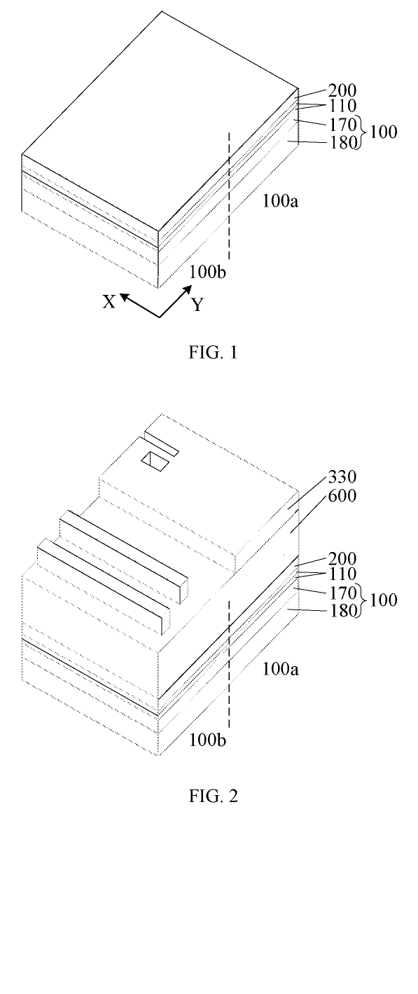

FIGS. 1 to 34 are schematic structural diagrams corresponding to steps of methods for forming a semiconductor structure according to embodiments of the present disclosure.

Referring to FIG. 1, a base 100 is provided. The base 100 includes a substrate 180 and a target material layer 170 over the substrate 180. A second core material layer 200 is formed over the base 100. The base 100 includes a first area 100a for forming first target structures and a second area 100b for forming second target structures. Both the first target structure and second target structure extend along a first direction (i.e., the X direction in FIG. 1). The pitch of adjacent first target structures is smaller than or equal to the pitch of adjacent second target structures.

The base 100 provides a process operation basis for formation processes of semiconductor structures. Exemplarily, the semiconductor structures include metal interconnection lines, barrier layers, adhesion layers, cap layers, etc.

In some embodiments, the substrate 180 is a wafer on which transistors and part of connection lines are formed.

In some embodiments, the base 100 includes the first area 100a used for forming multiple first target structures and a second area 100b used for forming multiple second target structures. The pitch of adjacent first target structures is smaller than or equal to the pitch of adjacent second target structures.

In some embodiments, during formation processes of a semiconductor structure, it is necessary to form denser first target structures and sparser second target structures. For example, the pitch of adjacent first target structures is smaller than or equal to the pitch of adjacent second target structures. The SAQP process may be used to form denser target structures. However, it is hard to use SAQP to create sparser target structures. In addition, the pitch between target structures is relatively fixed and difficult to adjust freely according to layout needs. When the SALELE process is used, the pitch between target structures may be defined according to the layout. Further, the pitch is easy to adjust, and a self-aligned block process may be realized. However, it is difficult to use SALELE to form denser (e.g., a pitch smaller than 38 nm) target structures. In some embodiments, the SAQP process is used in the first area 100a, and the SALELE process is used in the second area 100b. As such, the base 100 including the first area 100a for forming the first target structures and the second area 100b for forming the second target structures indicates the following may be achieved in some embodiments: Fabricating the first target structures with smaller pitches that are difficult to make with the SALELE process and fabricating the second target structures with larger pitches that are difficult to make with the SAQP process and having more freedom in design over the same base 100 (e.g., a same wafer).

In some embodiments, the first area 100a includes a logic device area. The second area 100b includes a peripheral device area. The logic device area has denser patterns, and the peripheral device area has sparser patterns. Optionally, the logical device area includes device areas containing a central processing unit (CPU) and a graphics processing unit (GPU), and the peripheral device area includes device areas containing static random-access memory (SRAM), input and output (IO) devices, etc.

Optionally, the pitch of adjacent first target structures is 24 nm to 38 nm and the pitch of adjacent second target structures is 38 nm to 200 nm.

The minimum pitch refers to the sum of the minimum width of the first target structure and the minimum spacing between adjacent first target structures when the first target structures and the second target structures are subsequently formed.

Thus, the SAQP process may be used to form the first target structures, and the SALELE process may be used to form the second target structures. The first target structures with a pitch of 24 nm to 38 nm and the second target structures with a pitch of 38 nm to 200 nm may be formed over the same base 100.

In some embodiments, the thickness of gate oxide layers in the logic device area is smaller than the thickness of gate oxide layers in the peripheral device area. Generally, the operating voltage of CPU or GPU transistors is lower than that of transistors in the IO device area. For example, the operating voltage of CPU transistors may be 0.75 V, while the operating voltage of transistors in an IO device area may be 1.2 V or even 1.8 V. Usually, in order to maintain the reliability and electrical performance of transistors in an IO device area, the gate oxide layer of transistors in the IO device area may be thicker than that in a logic device area. The thickness difference mainly comes from the thickness of a high-K (HK) dielectric layer of a high-K metal gate (HKMG) and the thickness of an interface layer (e.g., a silicon oxide layer) between transistor channels. Optionally, the interface layer in a gate oxide layer of the logic device area is thinner than that in the IO device area, and the HK dielectric layers over the interface layer in the two areas have the same thickness. The interface layer and HK dielectric layer together form a gate dielectric layer of a corresponding transistor. Thus, the thickness of a gate oxide layer in the logic device area is smaller than that in the peripheral device area.

The target material layer 170 is used to provide a process platform for forming the first target structures and the second target structures.

In some embodiments, in the step of providing the base 100, the target material layer 170 is a dielectric layer, the first target structures are first trenches, and the second target structures are second trenches.

The first trench and second trench provide spatial locations for subsequent processes. The target material layer 170 is a dielectric layer used to isolate structures formed in the first trench and second trench.

In some embodiments, materials of the dielectric layer include one or more of silicon oxide, silicon nitride, silicon oxynitride, silicon oxycarbide, silicon carbonitride, silicon oxynitride, a low-K (LK) material (e.g., a material of an LK dielectric layer), and an ultralow-K (ULK) material (e.g., a material of an ULK dielectric layer).

In some embodiments, in the step of providing the base 100, a mask material layer 110 is also formed between the target material layer 170 and the second core material layer 200.

The mask material layer 110 is used to subsequently form a second pattern transfer layer.

In some embodiments, the mask material layer 110 has a stacked structure, including a titanium nitride layer and a silicon oxide layer over the titanium nitride layer.

The second core material layer 200 is used to subsequently form second core layers and third core layers.

In some embodiments, after the second core layers are subsequently formed, the second core layers will be removed later. Thus, the material of the second core material layer 200 may be a material that is easy to remove, thereby reducing the difficulty of removing the second core layers and reducing the damage to other layers located below the second core material layer 200. Materials of the second core material layer 200 may include one or more of amorphous silicon (a-Si), polycrystalline silicon, single crystal silicon, silicon oxide, advanced patterning film (APF) material, spin on carbon (SOC), and silicon carbide. For example, the material of the second core material layer 200 may be a-Si in some cases.

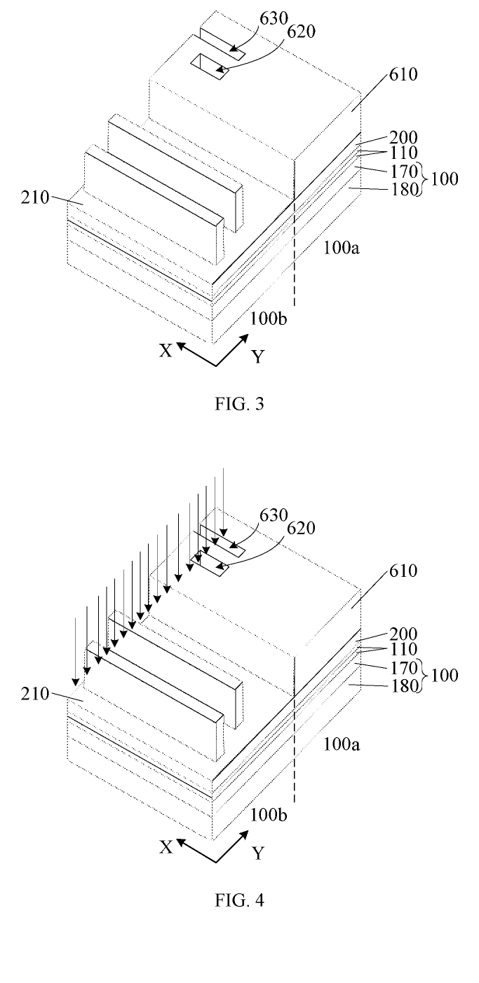

With reference to FIGS. 2 and 3, first protective layers 610 are formed on the second core material layer 200. The first protective layers 610 in the second area 100b are separately arranged.

The first protective layer 610 in the first area 100a is used to cover the first area 100a and protect the second core material layer 200 in the first area 100a from damage. The first protective layers 610 in the second area 100b are used as an implantation mask for subsequent ion implantation treatment on the second core material layer 200 in the second area 100b.

In some embodiments, in the step of forming the first protective layers 610 on the second core material layer 200, first openings 620 exposing the second core material layer 200 are formed in the first protective layer 610 located in the first area 100a, and the first openings 620 extend along the first direction.

The first openings 620 expose portions of the second core material layer 200 in the first area 100a and are used for subsequent modification treatment on the portions of the second core material layer 200 in the first area 100a through the first openings 620.

In some embodiments, in the step of forming the first protective layers 610 on the second core material layer 200, second openings 630 exposing the second core material layer 200 are also formed in the first protective layer 610 in the first area 100a. The second openings 630 extend along the first direction.

The second openings 630 expose portions of the second core material layer 200 in the first area 100a and are used for subsequent modification treatment on the portions of the second core material layer 200 in the first area 100a through the second openings 630.

The portion of the second core material layer 200 in the first area 100a that undergoes modification treatment through the first openings 620 is located at the extension position of subsequently formed second core layers. The portion of the second core material layer 200 in the first area 100a that undergoes modification treatment through the second openings 630 is located between adjacent second core layers that are subsequently formed.

In other embodiments, in the step of forming the first protective layers on the second core material layer, the first protective layer may cover the second core material layer in the first area, meaning the first protective layer completely covers the second core material layer in the first area without forming first openings.

Optionally, in some embodiments, the first openings 620 and the second openings 630 are arranged in parallel along the second direction (as shown by the Y direction in FIG. 3), and the second direction is perpendicular to the first direction.

In some embodiments, the material of the first protective layer 610 includes SOC material.

Optionally, referring to FIG. 2, the step of forming the first protective layers 610 that are separately arranged on the second core material layer 200 in the second area 100b and cover the second core material layer 200 in the first area 100a includes forming a first protective material layer 600 covering the second core material layer 200.

The first protective material layer 600 is used to form the first protective layers 610.

Correspondingly, in some embodiments, the first protective material layer 600 is a planarization layer. The material of the first protective material layer 600 includes SOC material. SOC is formed by a spin-coating process, which has low process cost. Moreover, using SOC helps improve the top surface flatness of the first protective material layer 600, thereby providing a good interface for formation of the first protective layer.

In some embodiments, second mask layers 330 are formed on the first protective material layer 600. The second mask layers 330 cover the first protective material layer 600 in the first area 100a and are separately set on the first protective material layer 600 in the second area 100b.

Optionally, in some embodiments, mask openings extending along the first direction are formed in the second mask layer in the first area 100a.

The second mask layers 330 are used to pattern the first protective material layer 600.

In some embodiments, the second mask layers 330 include an anti-reflection coating (Si-ARC) and a photoresist layer on the Si-ARC.

Referring to FIG. 3, the first protective material layer 600 in the second area 100b is patterned to form the first protective layers 610. Some portions of the first protective layers 610 are separately configured in the second area 100b. A part of the first protective material layer 600 covering the second core material layer 200 in the first area 100b is also retained to serve as other portions of the first protective layers 610.

Optionally, the first protective material layer 600 is patterned using the second mask layers 330 as an etch mask.

In some embodiments, after patterning the first protective material layer 600, the method further includes removing the second mask layers 330.

Referring to FIG. 4, a modification treatment is performed on the second core material layer 200 exposed in the second area 100b using the first protective layers 610 as a mask. A third core material layer 210 is formed that has an etch selectivity with the remaining second core material layer 200. The remaining second core material layer 200 is separately arranged in the second area 100b and surrounded by the third core material layer 210 in the second area 100b.

The modification treatment is performed on a portion of the second core material layer 200 in the second area 100b to obtain the third core material layer 210 having an etch selectivity with the second core material layer 200. This facilitates the subsequent removal of the remaining second core material layer 200 while minimizing damage to the third core material layer 210 during the removal process. The third core material layer 210 is used to prepare for subsequent patterning of the target material layer 170 in the second area 100b.

In some embodiments, in the step of performing the modification treatment on the second core material layer 200 exposed in the second area 100b using the first protective layers 610 as a mask, the modification treatment is also performed on the second core material layer 200 exposed by the first openings 620 in the first area 100a to form the third core material layer 210 located in the first area 100a.

Optionally, in some embodiments, by predefining positions of the first openings 620, the third core material layer 210 corresponding to the first openings 620 will subsequently be patterned by the first spacers and be arranged at positions below the first spacers.

In some embodiments, in the step of performing the modification treatment on the second core material layer 200 exposed in the second area 100b using the first protective layers 610 as a mask, the modification treatment is also performed on the second core material layer 200 exposed by the second openings 630 in the first area 100a to form the third core material layer 210 in the first area 100a.

Optionally, by predefining positions of the second openings 630, the third core material layer 210 corresponding to the second openings 630 is subsequently patterned by the first spacers and arranged below positions between adjacent first spacers.

In some embodiments, in the step of performing the modification treatment on the second core material layer 200 exposed in the second area 100b using the first protective layers 610 as a mask, an ion implantation treatment is performed on the second core material layer 200 using the first protective layer 610 as a mask, which forms the third core material layer 210 having an etch selectivity with the remaining second core material layer 200.

The ion implantation process offers uniform large-area ion implantation, more precise control of ion doping depth, and high repeatability. Using ion implantation treatment to obtain the third core material layer 210 facilitates accurate control of the doping concentration and distribution in the third core material layer 210, as well as the penetration depth into the second core material layer 200, resulting in a relatively uniform ion distribution in the third core material layer 210.

In some embodiments, in the step of performing ion implantation treatment on the second core material layer 200 using the first protective layers 610 as a mask, the ions implanted during the ion implantation treatment include one or more of boron, phosphorus, arsenic, boron chloride, boron dichloride, and carbon.

In some embodiments, the material of the second core material layer 200 is a-Si. Implanting one or more ions of boron, phosphorus, arsenic, boron chloride, boron dichloride, and carbon into the second core material layer 200 may transform the a-Si into a material with high etch selectivity to a-Si, thereby obtaining the third core material layer 210 with high etch selectivity to the second core material layer 200.

In some embodiments, one mask and a lithography-etch process are used to pattern the second mask layers 330 in the second area 100b and the first area 100a. The second mask layers 330 are used to pattern the first protective material layer 600 to form the first protective layers 610. Then, the first protective layers 610 are used as a mask to perform ion implantation treatment on the second core material layer 200, forming the third core material layer 210 with etch selectivity to the second core material layer 200. The process for forming the first protective layers 610 offers high flexibility, and the width dimensions and pitch of the first protective layers 610 are easily adjustable. Accordingly, the width dimensions and pitch of the separately arranged remaining second core material layer 200 in the second area 100b are also easily adjustable, enabling the formation of some second target structures with larger pitches in the second area 100b and improving design freedom in patterning.

Optionally, in some embodiments, in the step of performing the modification treatment on a portion of the second core material layer 200 in the second area 100b using the first protective layers 610 as a mask, the remaining second core material layer 200 has a dimension of 35 nm to 200 nm along the second direction (as shown by the Y direction in FIG. 4) and a pitch of 76 nm to 200 nm. The third core material layer 210 has a dimension of 35 nm to 200 nm along the second direction and a pitch of 76 nm to 200 nm.

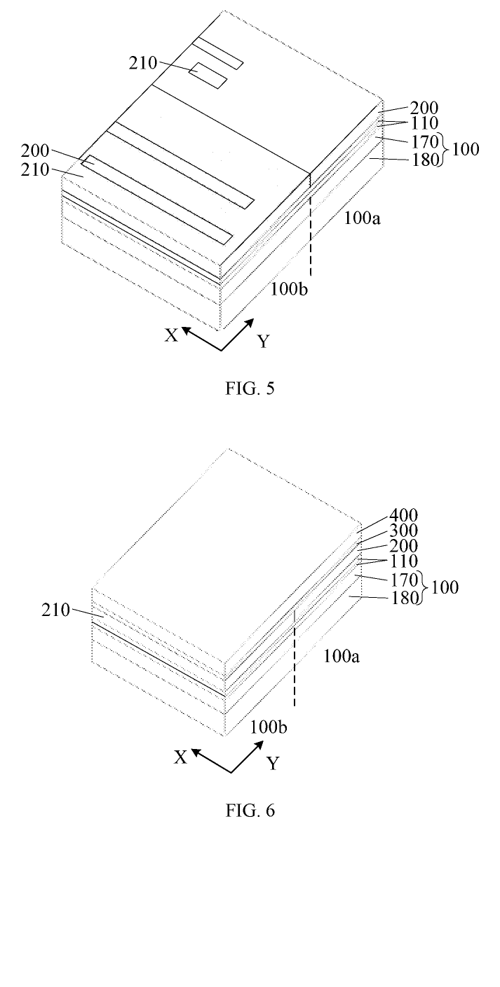

Referring to FIG. 5, the first protective layers 610 are removed.

Removing the first protective layers 610 prepares for the subsequent formation of the first core material layer.

In some embodiments, an etch process is used to remove the first protective layers 610.

In some embodiments, either an isotropic or an anisotropic etch process may be used, as long as the etch selectivity of the process is ensured. The etch process should have high etch selectivity between the first protective layers 610 and the second core material layer 200, and between the first protective layers 610 and the third core material layer 210. This minimizes damage to the second core material layer 200 and the third core material layer 210 during the removal of the first protective layers 610.

Referring to FIG. 6, before subsequently forming the first core material layer covering the second core material layer 200 and the third core material layer 210, the method further includes forming an etch stop layer 300 covering the second core material layer 200 and the third core material layer 210.

The etch stop layer 300 is used for the subsequent formation of a first pattern transfer layer. The etch stop layer 300 also serves as an etch stop during the subsequent patterning of the first core material layer and protects the second core material layer 200 from damage.

In some embodiments, the material of the etch stop layer 300 includes one or more of silicon oxide, silicon nitride, silicon oxynitride, silicon carbide, titanium, titanium oxide, titanium nitride, tantalum, tantalum oxide, tantalum nitride, boron nitride, copper nitride, aluminum nitride, and tungsten nitride. In cases below, an exemplary material of the etch stop layer 300 may be silicon oxide.

Continuing to refer to FIG. 6, a first core material layer 400 covering the second core material layer 200 and the third core material layer 210 is formed.

The first core material layer 400 is used to subsequently form first core layers.

In some embodiments, after the first core layers are subsequently formed, the first core layers will be removed later. Therefore, the material of the first core material layer 400 is a material that is easily removed, reducing the difficulty of removing the first core layers and minimizing damage to other layers below the first core material layer 400. Optionally, the material of the first core material layer 400 includes one or more of a-Si, polycrystalline silicon, single-crystal silicon, silicon oxide, APF material, SOC, and silicon carbide. In some embodiments, the material of the first core material layer 400 is a-Si.

Correspondingly, in some embodiments, in the step of forming the first core material layer 400 covering the second core material layer 200 and the third core material layer 210, the first core material layer 400 covers the etch stop layer 300.

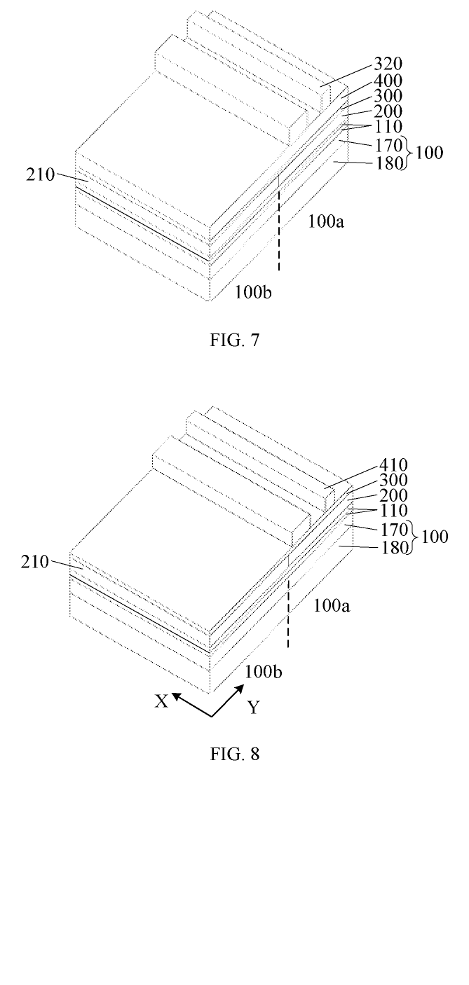

With reference to FIGS. 7 and 8, the first core material layer 400 is patterned to form separate first core layers 410 in the first area 100a. The first core layers 410 extend along a first direction (e.g., the X direction in FIG. 8) and are arranged in parallel along a second direction (e.g., the Y direction in FIG. 8). The first direction is perpendicular to the second direction.

The first core layers 410 are used to provide support for the subsequent formation of the first spacers.

In some embodiments, a dry etch process is used to pattern the first core material layer 400. The dry etch of a-Si may easily stop on the silicon oxide material which serves as the first etch stop layer 300 in some embodiments.

The dry etch process is a dry etch process with anisotropic etching characteristics, where the vertical etch rate is much greater than the lateral etch rate. Therefore, selecting the dry etch process helps improve pattern transfer accuracy. Additionally, dry etching is more directional, which helps improve the sidewall morphology quality and dimensional accuracy of the first core layers 410.

Correspondingly, in some embodiments, the material of the first core layers 410 is a-Si, which reduces damage to the etch stop layer 300 during the patterning of the first core material layer 400. After patterning the first core material layer 400, the etch stop layer 300 maintains good dimensional and morphological accuracy. The first core layers 410 are made of a material that is easy to be removed, and the subsequent process of removing the first core layers 410 has minimal impact on the etch stop layer 300.

In some embodiments, dimensions and pitch of the first core layers 410 are set according to the dimensions and pitch of the first target structures to be formed subsequently in the first area 100a.

Referring to FIG. 7, the step of patterning the first core material layer 400 includes forming first mask layers 320 on the first core material layer 400 that are separate in the first area 100a.

The first mask layers 320 are used as an etch mask for patterning the first core material layer 400.

In some embodiments, the first mask layers 320 include an SOC layer, Si-ARC on the SOC, and a photoresist layer on the Si-ARC. The first mask layers 320 may be formed through lithography and several etch steps.

Referring to FIG. 8, the first core material layer 400 is patterned via the first mask layers 320 to form separate first core layers 410 in the first area 100a.

In some embodiments, after forming the first core layers 410, the method further includes removing the first mask layers 320.

Removing the first mask layers 320 prepares for the subsequent formation of the first spacers.

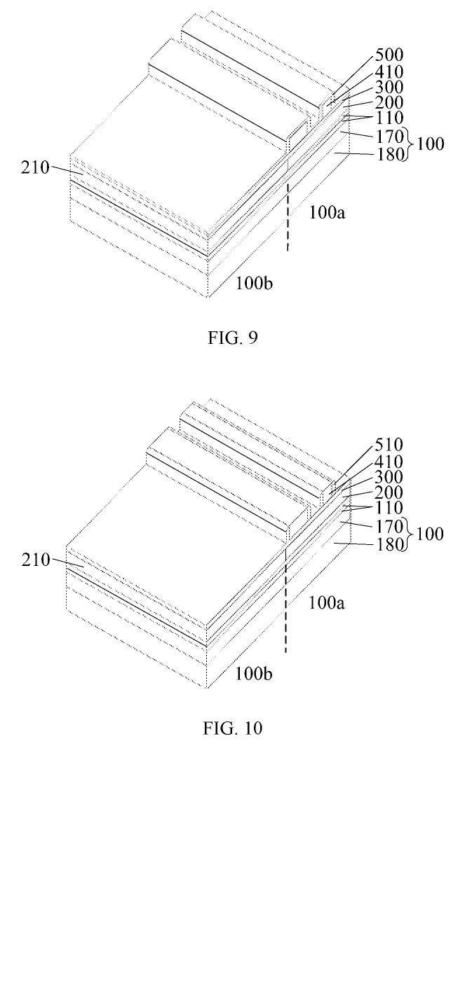

With reference to FIGS. 9 and 10, first spacers 510 covering sidewalls of the first core layers 410 are formed.

The first spacers 510 are used as an etch mask for subsequently patterning the second core material layer 200.

In some embodiments, the material of the first spacers 510 includes one or more of titanium oxide, titanium nitride, silicon oxide, silicon nitride, silicon oxynitride, and silicon carbide.

Titanium oxide, titanium nitride, silicon oxide, silicon nitride, silicon oxynitride, and silicon carbide may provide good etch selectivity with the first core layers 410, thereby minimizing damage to the first spacers 510 during the subsequent step of removing the first core layers 410.

Optionally, referring to FIG. 9, the step of forming the first spacers 510 covering sidewalls of the first core layers 410 includes forming a first spacer material layer 500 covering sidewalls and tops of the first core layers 410 and above the second core material layer 200 and the third core material layer 210.

Optionally, the first spacer material layer 500 covers sidewalls and tops of the first core layers 410 and the top of the etch stop layer 300.

The first spacer material layer 500 is used to directly form the first spacers 510. Correspondingly, the material of the first spacer material layer 500 includes one or more of titanium oxide, titanium nitride, silicon oxide, silicon nitride, silicon oxynitride, and silicon carbide.

In some embodiments, an ALD process is used to form the first spacer material layer 500 that covers sidewalls and tops of the first core layers 410 and the top of the etch stop layer 300.

The first spacer material layer 500 formed by the ALD process has excellent thickness uniformity and good step coverage capability, allowing the first spacer material layer 500 to conformally cover sidewalls and tops of the first core layers 410 and the top of the etch stop layer 300 very well.

Referring to FIG. 10, the first spacer material layer 500 on the tops of the first core layers 410 and above the second core material layer 200 and the third core material layer 210 is removed. Portions of the first spacer material layer 500 on the sidewalls of the first core layers 410 are retained as the first spacers 510.

Optionally, the first spacer material layer 500 located on the tops of the first core layers 410 and the etch stop layer 300 is removed.

In some embodiments, a dry etch process is used to remove the first spacer material layer 500 on the tops of the first core layers 410 and the etch stop layer 300.

The dry etch process is an anisotropic etch process. Therefore, selecting the dry etch process helps minimize damage to the first core layers 410 and the etch stop layer 300. Additionally, dry etching is more directional, which helps improve the sidewall morphology quality and dimensional accuracy of the first spacers 510.

Referring to FIG. 11, the first core layers 410 are removed.

Removing the first core layers 410 prepares for subsequently patterning the second core material layer 200 and the third core material layer 210 using the first spacers 510 as a mask.

In some embodiments, a wet etch process is used to remove the first core layers 410.

The wet etch process has isotropic etching characteristics, which facilitates complete removal of the first core layers 410. Moreover, the wet etch process has relatively low cost, simple operation steps, and may achieve high etch selectivity. This helps minimize damage to the first spacers 510 during the removal of the first core layers 410.

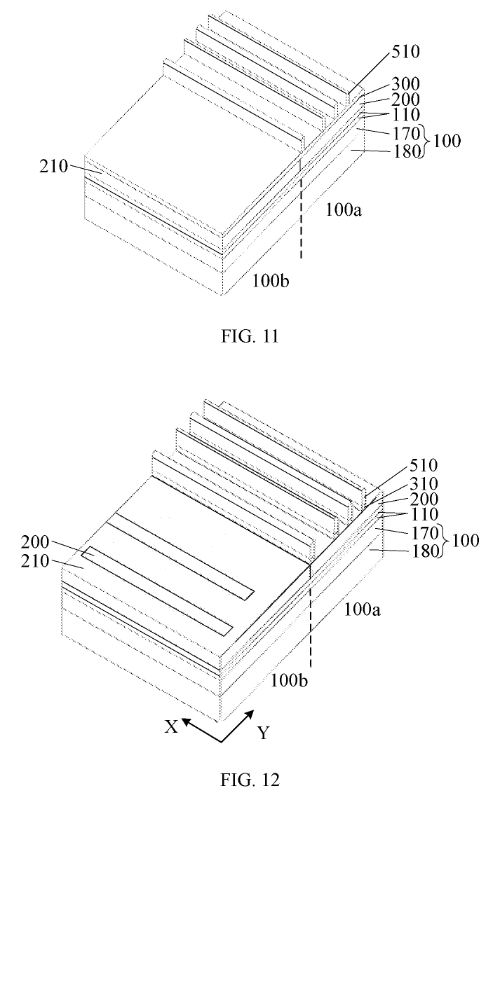

Referring to FIG. 12, before subsequently forming the second protective layer on the second core material layer 200 in the second area 100b, the method further includes patterning the etch stop layer 300 using the first spacers 510 as a mask and forming first pattern transfer layers 310.

The first pattern transfer layers 310 are used as an etch mask for subsequently patterning the second core material layer 200 and the third core material layer 210 in the first area 100a.

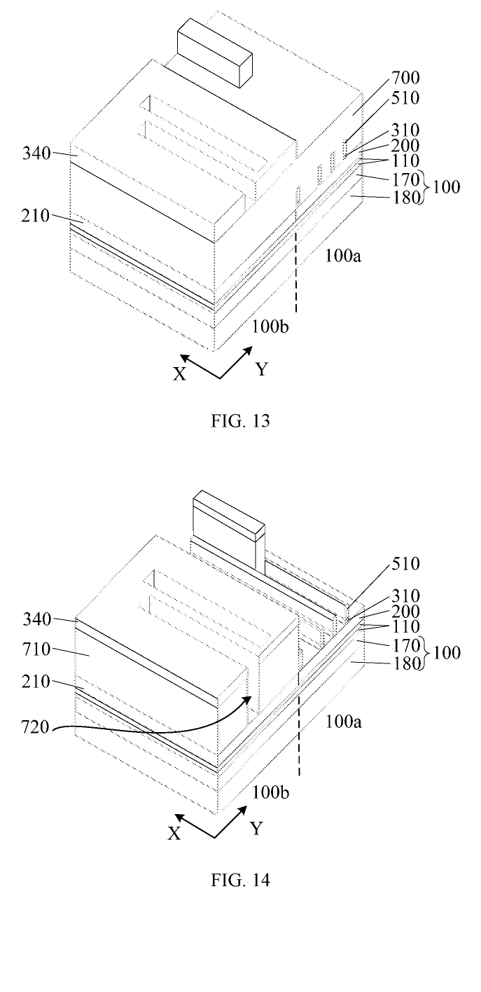

With reference to FIGS. 13 and 14, a second protective layer 710 is formed on the second core material layer 200 and the third core material layer 210 in the second area 100b. Separate second protective layer openings 720 extending along the first direction and arranged in parallel along the second direction are formed in the second protective layer 710.

The second protective layer 710 is used as an etch mask for subsequently patterning the second core material layer 200 and the third core material layer 210.

In some embodiments, in the step of forming the second protective layer 710 on the second core material layer 200 and the third core material layer 210 in the second area 100b, the second protective layer 710 is also formed on the third core material layer 210 in the first area 100a.

The second protective layer 710 is also formed on the third core material layer 210 in the first area 100a, so that when the second core material layer 200 and the third core material layer 210 are subsequently patterned via the second protective layer 710, the third core material layer 210 corresponding to the second protective layer 710 in the first area 100a is retained.

Optionally, the second protective layer 710 is formed on the third core material layer 210 corresponding to the second openings 630 and fills the space between adjacent first spacers 510. Simultaneously, the first spacers 510 span across the third core material layer 210 corresponding to the first openings 620 along the first direction.

In some embodiments, the second protective layer 710 is obtained through patterning a planarization layer. The material of the second protective layer 710 includes SOC material or SOC and a residual portion of a third mask layer 340. The presence or absence of the residual third mask layer 340 depends on process selection and does not affect subsequent steps. SOC is formed by a spin-coating process, which has low process cost. Moreover, using SOC helps improve the top surface flatness of the planarization layer, thereby providing a good interface for the formation of the second protective layer 710.

Referring to FIG. 13, the step of forming the second protective layer 710 on the second core material layer 200 and the third core material layer 210 in the second area 100b includes forming a second protective material layer 700 covering the second core material layer 200, the third core material layer 210, the first spacers 510, and sidewalls of the first pattern transfer layers 310.

In some embodiments, a third mask layer 340 is also formed on the second protective material layer 700. Separate mask openings extending along the first direction and arranged in parallel along the second direction are formed in the third mask layer 340 in the second area 100b. The third mask layer 340 in the first area 100a is located above the third core material layer 210 in the first area 100a.

The third mask layer 340 is used to pattern the second protective material layer 700.

In some embodiments, the third mask layer 340 includes Si-ARC and a photoresist layer on the Si-ARC.

In some embodiments, one mask and related lithography and etch processes are used to pattern the third mask layer 340 in the first area 100a and the second area 100b. The third mask layer 340 is used to pattern the second protective material layer 700 to form the second protective layer 710. Then, the second core material layer 200 and the third core material layer 210 are patterned using the second protective layer 710 in the second area 100b and the first spacers 510 in the first area as a mask, forming third core layers 230 with etch selectivity to second core layers 220. Using one mask to define the third mask layer 340 offers high process flexibility and diverse patterns, allowing relatively free design within the limits of a single lithography step. That is, the dimensions and pitch of the second protective layer openings 720 in the second protective layer 710 are relatively free, as long as they comply with rules such as the single DUV lithography limit and a pitch greater than about 76 nm. Accordingly, the design of the relative dimensions and pitch of subsequent trenches surrounded by the second spacer material layer supported by sidewalls of the second core layers 220 and third core layers 230 becomes relatively free. This enables the formation of some second target structures with larger pitches in the second area 100b and improves design freedom in patterning.

Referring to FIG. 14, the second protective material layer 700 is patterned. The second protective material layer 700 in the first area 100a is removed. The first spacers 510 in the first area 100a are exposed. Portions of the second protective material layer 700 extending along the first direction and the second direction in the second area 100b are removed. Remaining portions of the second protective material layer 700 in the second area 100b are retained as the second protective layer 710.

Optionally, the second protective material layer 700 is patterned using the third mask layer 340 as an etch mask.

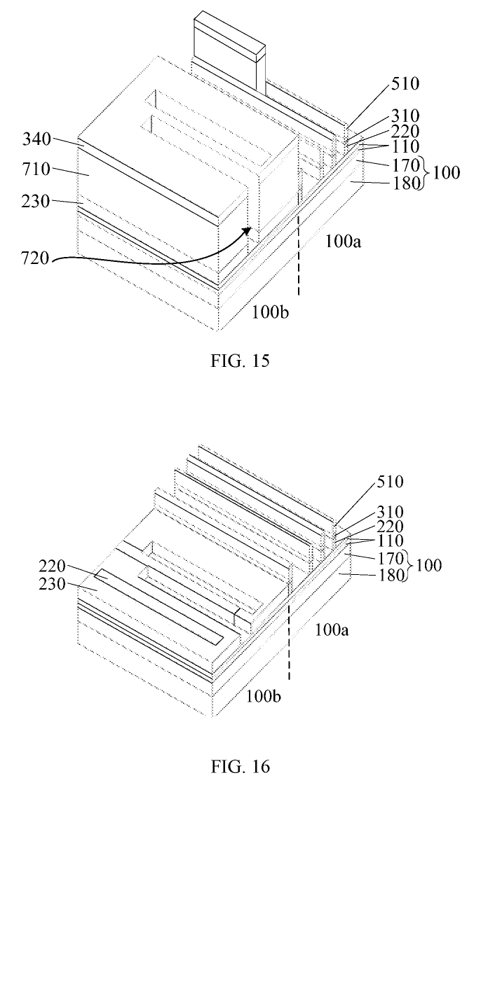

Referring to FIG. 15, the second core material layer 200 and the third core material layer 210 are patterned using the first spacers 510 and the second protective layer 710 as a mask, forming the second core layers 220 corresponding to the second core material layer 200 and the third core layers 230 corresponding to the third core material layer 210.

Optionally, the second core layers 220 are formed by patterning the second core material layer 200, while the third core layers 230 are formed by patterning the third core material layer 210. The etch selectivity between the original second core material layer 200 and the third core material layer 210, resulted from the modification treatment, is not lost during the patterning process. That is, the second core layers 220 and the third core layers 230 still retain high etch selectivity. For example, during etching in KOH or SC1 solution, the second core layers 220 will be removed at a faster etch rate, while the third core layers 230 experience almost no loss.

After subsequently removing the second core layers 220, the third core layers 230 serve as part of the etch mask for patterning the target material layer 170 in the second area 100b and also provide support for subsequent formation of the second spacers.

Correspondingly, in some embodiments, the material of the second core layers 220 is a-Si, and the material of the third core layers 230 is a-Si doped with boron, phosphorus, or arsenic.

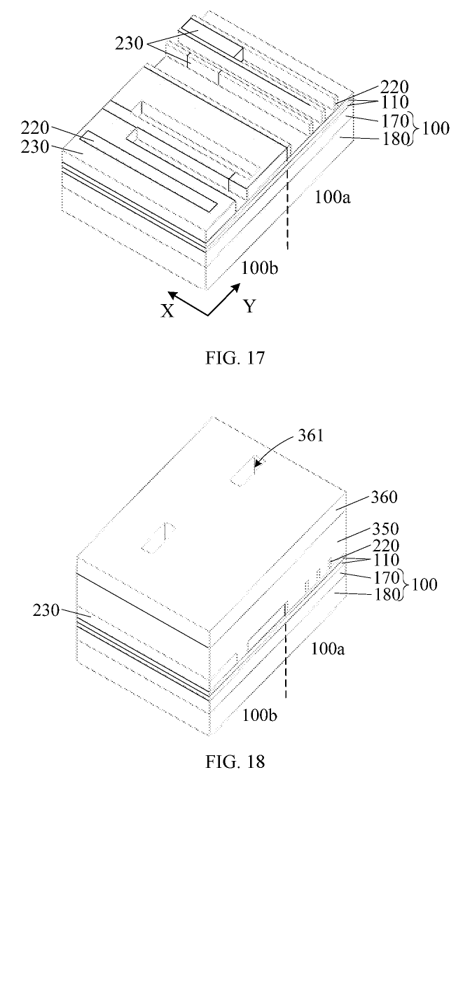

In some embodiments, in the step of patterning the second core material layer 200 and the third core material layer 210 using the first spacers 510 and the second protective layer 710 as a mask, the third core material layer 210 in the first area 100a is also patterned using the first spacers 510 to form the third core layers 230. In the first area 100a, the second core layers 220 and the third core layers 230 corresponding to portions of the first spacers 510 are alternately distributed along the first direction (as shown in FIG. 17).

In some embodiments, the third core material layer 210 is also formed in the first area 100a, and then the third core material layer 210 in the first area 100a is patterned to form the third core layers 230 in the first area 100a. When the target material layer 170 is subsequently patterned using the second spacers and the third core layers 230 as a mask, the target material layer 170 corresponding to the third core layers 230 in the first area 100a is retained to block the formation of some first target structures. Therefore, in some embodiments, some redundant first target structures in the first area 100a made by the SAQP process may be removed without adding masks and process steps.

Simultaneously, in some embodiments, in the step of patterning the second core material layer 200 and the third core material layer 210 using the first spacers 510 and the second protective layer 710 as a mask, the third core material layer 210 under the second protective layer 710 in the first area 100a is also retained as the third core layers 230 (as shown in FIG. 17).

In some embodiments, the third core material layer 210 is also formed in the first area 100a, and the second protective layer 710 is used to protect the third core material layer 210 in the first area 100a. This ensures that in the step of patterning the second core material layer 200 and the third core material layer 210 using the first spacers 510 and the second protective layer 710 as a mask, the third core material layer 210 in the first area 100a is retained as the third core layers 230 in the first area 100a. When the target material layer 170 is subsequently patterned using the second spacers and the third core layers 230 as a mask, the target material layer 170 corresponding to the third core layers 230 in the first area 100a is retained to block the formation of some first target structures. Therefore, in some embodiments, some redundant first target structures in the first area 100a made by the SAQP process may be removed without adding masks and process steps.

In some embodiments, in the step of patterning the second core material layer 200 and the third core material layer 210 using the first spacers 510 and the second protective layer 710 as a mask, the second core material layer 200 in the first area 100a is patterned using the first pattern transfer layer 310 as a mask to form separate second core layers 220 in the first area 100a.

Optionally, in the step of patterning the second core material layer 200 and the third core material layer 210 using the first spacers 510 and the second protective layer 710 as a mask, the third core material layer 210 in the first area 100a is also patterned using the first pattern transfer layer 310 as a mask to form separate third core layers 230 in the first area 100a. The third core material layer 210 patterned using the first pattern transfer layer 310 as a mask is the third core material layer 210 corresponding to the first openings 620.

The second core material layer 200 and the third core material layer 210 in the first area 100a are patterned using the first pattern transfer layer 310 as a mask, forming separate second core layers 220 and third core layers 230 in the first area 100a. It helps improve pattern transfer accuracy, thereby enhancing the dimensional accuracy of the second core layers 220 and the third core layers 230.

Optionally, the second core layers 220 and the third core layers 230 in the first area 100a are transferred from the first spacers 510. The pitch of the first spacers 510 has already been halved based on the pitch of the first mask layer 320, which is an SADP process. It achieves a reduction from the single DUV lithography-etch limit of about 80 nm to about 40 nm. This prepares for the subsequent formation of second spacers on sidewalls of the second core layers 220 and the third core layers 230, which will further halve the pitch compared to the first spacers 510. This is also a characteristic of the SAQP process, and the reason why SAQP may form patterns with pitches around 24 nm.

Referring to FIGS. 16 and 17, the first spacers 510 and the second protective layer 710 are removed.

Removing the first spacers 510 and the second protective layer 710 prepares for the subsequent removal of the second core layers 220.

Referring to FIG. 16, a dry etch process is used to remove the second protective layer 710.

In some embodiments, either an isotropic or an anisotropic etch process may be used, as long as the etch selectivity of the process is ensured. The etch process should have high etch selectivity between the second protective layer 710 and the second core layers 220, and between the second protective layer 710 and the third core layers 230. This minimizes damage to the second core layers 220 and the third core layers 230 during the removal of the second protective layer 710.

Referring to FIG. 17, the first spacers 510 are removed.

Removing the first spacers 510 prepares for the subsequent formation of the second spacers.

In some embodiments, after forming the second core layers 220 and the third core layers 230, the method further includes removing the first pattern transfer layer 310.

Removing the first pattern transfer layer 310 prepares for the subsequent formation of the second spacers.

In some embodiments, a wet etch process is used to remove the first spacers 510 and the first pattern transfer layer 310.

The wet etch process has isotropic etching characteristics, which facilitates complete removal of the first spacers 510 and the first pattern transfer layer 310. Moreover, the wet etch process has relatively low cost, simple operation steps, and can achieve high etch selectivity. This helps minimize damage to the second core layers 220 and the third core layers 230 during the removal of the first spacers 510 and the first pattern transfer layer 310.

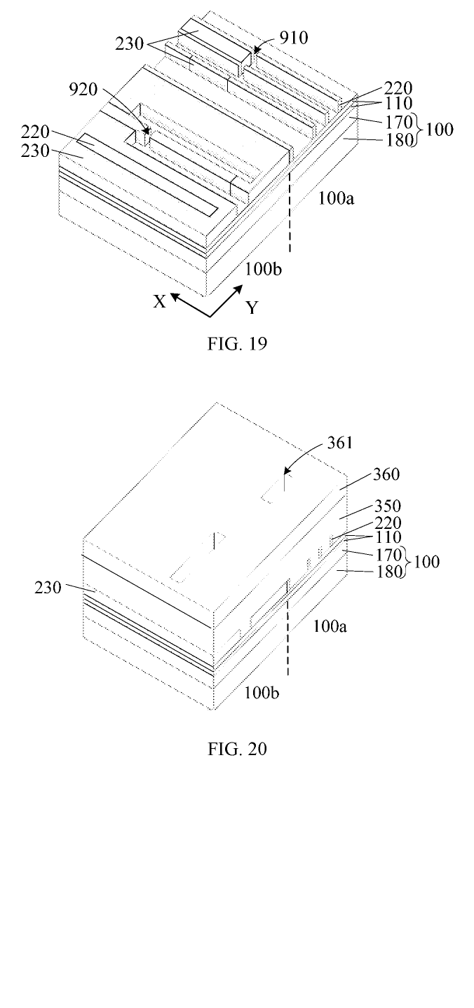

With reference to FIGS. 18 and 19, after removing the second protective layer 710 and before subsequently forming the second spacers covering sidewalls of the second core layers 220 and the third core layers 230, the method further includes patterning a portion of the second core layers 220 in the first area 100a, and a portion of the second core layers 220 and the third core layers 230 in the second area 100b, and forming first separation openings 910 that separate the second core layers 220 in the first area 100a along the first direction, and second separation openings 920 that separate the second core layers 220 in the second area 100b along the first direction.

The first separation openings 910 are used to subsequently form first separation structures, and the second separation openings 920 are used to subsequently form second separation structures.

Optionally, the step of patterning a portion of the second core layers 220 in the first area 100a, and a portion of the second core layers 220 and the third core layers 230 in the second area 100b, and forming the first separation openings 910 that separate the second core layers 220 in the first area 100a along the first direction, and the second separation openings 920 that separate the second core layers 220 in the second area 100b along the first direction, includes: referring to FIG. 18, forming a third protective layer 350 covering the second core layers 220 and the third core layers 230. A fourth mask layer 360 is formed on the third protective layer 350. Fourth mask layer openings 361 are formed in the fourth mask layer 360, extending along the second direction across the second core layers 220 in the first area 100a and the second area 100b. Referring to FIG. 19, the second core layers 220 are patterned through the third protective layer 350 and the fourth mask layer openings 361, forming the first separation openings 910 that separate the second core layers 220 in the first area 100a along the first direction, and forming the second separation openings 920 that separate the second core layers 220 in the second area 100b along the first direction.

In some embodiments, the third protective layer 350 is a planarization layer. The material of the third protective layer 350 includes SOC material. SOC is formed by a spin-coating process, which has low process cost. Moreover, using SOC helps improve the top surface flatness of the third protective layer 350, thereby providing a good interface for the formation of the fourth mask layer 360.

The fourth mask layer 360 is used to pattern the second core layers 220 along with the third protective layer 350.

In some embodiments, the fourth mask layer 360 includes Si-ARC and a photoresist layer on the Si-ARC.

Continuing to refer to FIG. 19, after forming the first separation openings 910 that separate the second core layers 220 in the first area 100a along the first direction and the second separation openings 920 that separate the second core layers 220 in the second area 100b along the first direction, the method further includes removing the third protective layer 350 and the fourth mask layer 360.

In some process flows, based on practical process requirements, the steps described in FIGS. 18 and 19 may be repeated to form additional first separation openings 910 and second separation openings 920 at target locations.

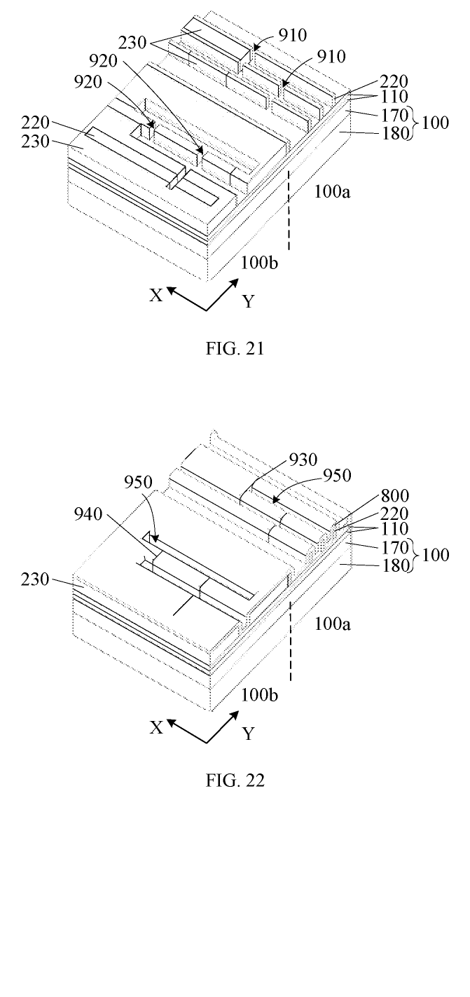

As an example, the steps for forming the first separation openings 910 and the second separation openings 920 are performed twice, as shown in FIGS. 20 and 21. A third protective layer 350 covering the second core layers 220 and the third core layers 230 is formed. A fourth mask layer 360 is formed on the third protective layer 350. Fourth mask layer openings 361 are formed in the fourth mask layer 360, which extend along the second direction across the second core layers 220 in the first area 100a and across the second core layers 220 in the second area 100b. The second core layers 220 are patterned through the third protective layer 350 and the fourth mask layer openings 361. The first separation openings 910 are formed that separate the second core layers 220 in the first area 100a along the first direction. The second separation openings 920 are formed that separate the second core layers 220 in the second area 100b along the first direction.

With reference to FIGS. 22 to 28, second spacers 810 covering sidewalls of the second core layers 220 and the third core layers 230 are formed.

The second spacers 810 are used as part of an etch mask for subsequently patterning the target material layer 170 in the first area 100a and the second area 100b.

In some embodiments, the material of the second spacers 810 includes one or more of titanium oxide, titanium nitride, silicon oxide, silicon nitride, silicon oxynitride, and silicon carbide.

Titanium oxide, titanium nitride, silicon oxide, silicon nitride, silicon oxynitride, and silicon carbide may provide good etch selectivity with the second core layers 220 and the third core layers 230, thereby minimizing damage to the second spacers 810 during subsequent steps of removing the second core layers 220.

In some embodiments, in the step of forming the second spacers 810 covering sidewalls of the second core layers 220 and the third core layers 230, the second spacers 810 also cover sidewalls of the first separation openings 910 and the second separation openings 920. Twice the thickness of the second spacer 810 is larger than the dimension of the first separation openings 910 and the second separation openings 920 along the first direction. Therefore, the second spacers 810 on opposite sidewalls of the first separation openings 910 contact each other, forming first separation structures 930. The second spacers 810 on opposite sidewalls of the second separation openings 920 contact each other, forming second separation structures 940.

The first separation structures 930 and the second separation structures 940 are used to transfer the pattern to the target material layer 170, enabling the direct formation of separation for the first target structures and the second target structures in the target material layer 170. After subsequent patterning of the target material layer 170, when the first target structures and the second target structures are formed, some first target structures, which need separation, are separated, and some second target structures, which need separation, are also separated.

Optionally, referring to FIG. 22, the step of forming the second spacers 810 covering sidewalls of the second core layers 220 and the third core layers 230 includes forming a second spacer material layer 800 covering sidewalls and tops of the second core layers 220 and the third core layers 230 and the top of the base 100.

The second spacer material layer 800 is used to directly form the second spacers 810. Correspondingly, the material of the second spacer material layer 800 includes one or more of titanium oxide, titanium nitride, silicon oxide, silicon nitride, silicon oxynitride, and silicon carbide.

In some embodiments, an ALD process is used to form the second spacer material layer 800 covering sidewalls and tops of the second core layers 220 and the third core layers 230 and the top of the base 100.

The second spacer material layer 800 formed by the ALD process has excellent thickness uniformity and good step coverage capability, enabling the second spacer material layer 800 to conformally cover sidewalls and tops of the second core layers 220 and the third core layers 230 and the top of the base 100.

In some embodiments, in the step of forming the second spacer material layer 800 covering sidewalls and tops of the second core layers 220 and the third core layers 230 and the top of the base 100, the second spacer material layer 800 also fills the first separation openings 910 and the second separation openings 920.

Optionally, the second spacer material layer 800 covering sidewalls of the second core layers 220 and the third core layers 230 serves as the second spacers 810. The second spacer material layer 800 filling the first separation openings 910 serves as first separation structures 930. The second spacer material layer 800 filling the second separation openings 920 serves as second separation structures 940.

In some embodiments, in the step of forming the second spacer material layer 800 covering sidewalls and tops of the second core layers 220 and the third core layers 230 and the top of the base 100, the second spacer material layer 800 on opposite sidewalls surround and form trenches 950.

Optionally, the first separation structures 930 only separate first target structures corresponding to (directly below) the second core layers 220 in the first area 100a, and do not separate trenches 950 surrounded by the second spacers 810 of the second core layers 220 in the first area 100a and first target structures corresponding to the trenches 950. This is also the special feature of the SAB technology mentioned in the background. Similarly, the second separation structures 940 only separate second target structures corresponding to the second core layers 220 in the second area 100b, and do not separate the second target structures corresponding to the trenches 950 surrounded by the second spacer material layer 800 on sidewalls of the third core layers 230 and the second core layers 220 in the second area 100b.

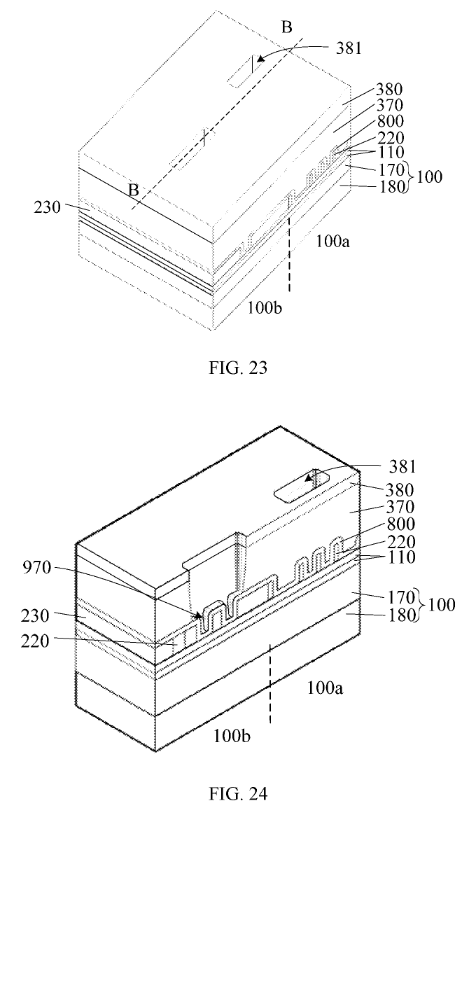

With reference to FIGS. 23 to 27, after forming the second spacer material layer 800 covering sidewalls and tops of the second core layers 220 and the third core layers 230 and the top of the base 100, and before subsequently removing the second spacer material layer 800 on the tops of the second core layers 220, the third core layers 230, and the base 100, the method further includes forming third separation structures 960 extending along the second direction and contacting the second spacers 810 in the trenches 950 of the first area 100a and the second area 100b. The third separation structures 960 separate the trenches 950 along the first direction.

The third separation structures 960 are used to transfer the pattern to the target material layer 170, enabling the direct formation of separation at the first target structures and the second target structures corresponding to the trenches 950 in the first area 100a and the second area 100b in the target material layer 170. After subsequent patterning of the target material layer 170, while the first target structures and the second target structures are formed in the target material layer 170, the first target structures that need separation are separated, and the second target structures that need separation are separated.

Optionally, the third separation structures 960 only separate first target structures corresponding to (directly below) the trenches 950 in the first area 100a, and do not separate first target structures corresponding to the second core layers 220 in the first area 100a. This is also the special feature of the SAB technology mentioned in the background. Similarly, the third separation structures 960 only separate second target structures corresponding to the trenches 950 in the second area 100b, and do not separate second target structures corresponding to the second core layers 220 in the second area 100b.

Optionally, in the first area 100a, the separation transferred to the target material layer 170 by the third separation structures 960 and the separation transferred to the target material layer 170 by the first separation structures 930 are separations of adjacent first target structures. In the second area 100b, the separation transferred to the target material layer 170 by the third separation structures 960 and the separation transferred to the target material layer 170 by the second separation structures 940 are separations of adjacent second target structures. Thus, by pre-forming the first separation structures 930, the second separation structures 940, and the third separation structures 960, adjacent first target structures or adjacent second target structures are simultaneously separated in the target material layer 170, providing an excellent formation method for separations with smaller pitches.

FIG. 24 is a cross-sectional view along a line BB in FIG. 23. With reference to FIGS. 23 and 24, optionally, the step of forming the third separation structures 960 extending along the second direction and contacting the second spacers 810 in the trenches 950 of the first area 100a and the second area 100b includes forming a fourth protective layer 370 covering the second spacer material layer 800 and filling the trenches 950. A fifth mask layer 380 is formed on the fourth protective layer 370. Fifth mask layer openings 381 extending along the second direction and crossing the trenches 950 are formed in the fifth mask layer 380. The fourth protective layer 370 is patterned through the fifth mask layer openings 381 to remove part of the fourth protective layer 370 in positions corresponding to the trenches 950 and the fifth mask layer openings 381, forming third separation openings 970.

In some embodiments, the fourth protective layer 370 is a planarization layer. The material of the fourth protective layer 370 includes SOC material. SOC is formed by a spin-coating process, which has low process cost. Moreover, using SOC helps improve the top surface flatness of the fourth protective layer 370, thereby providing a good interface for the formation of the fifth mask layer 380.

The fifth mask layer 380 is used to pattern the fourth protective layer 370 to form the third separation openings 970.

In some embodiments, the fifth mask layer 380 includes Si-ARC and a photoresist layer on the Si-ARC.

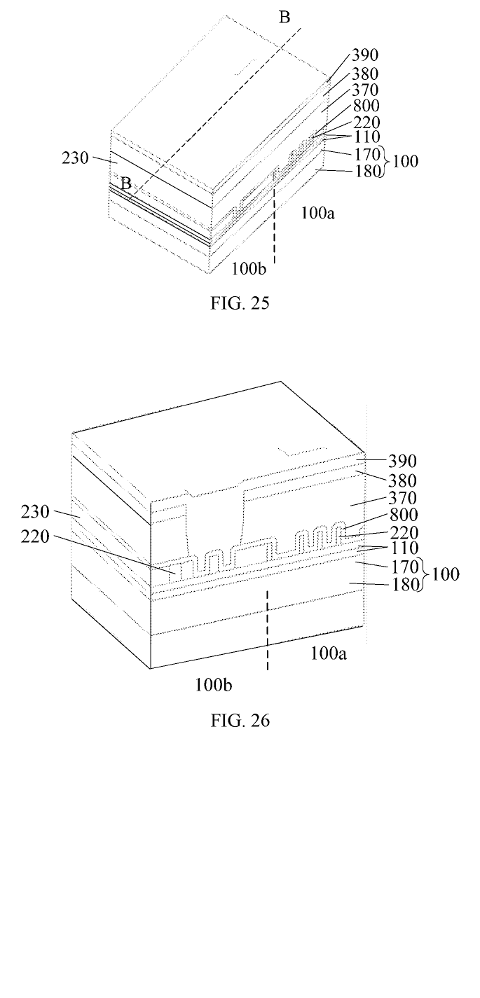

With reference to FIGS. 25 and 26, where FIG. 26 is a cross-sectional view along a line BB in FIG. 25, a separation material layer 390 filling the third separation openings 970 is formed.

The separation material layer 390 is used to form the third separation structures 960.

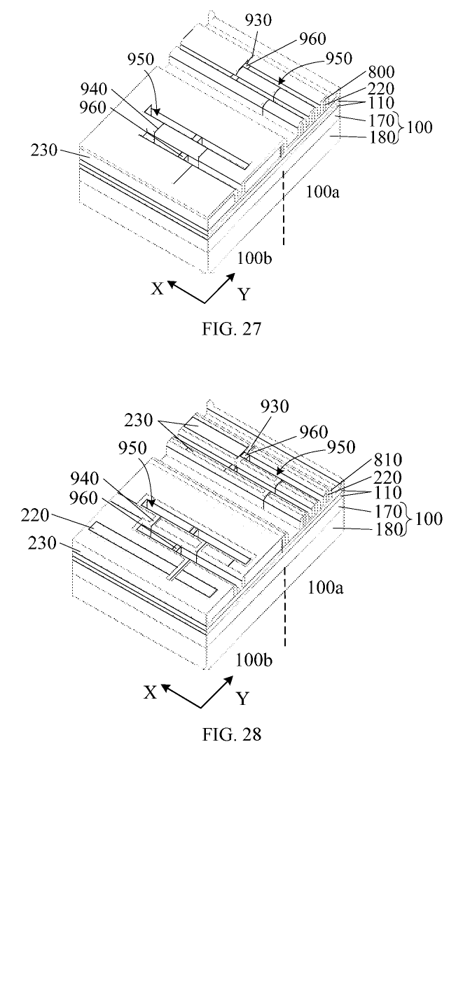

Referring to FIG. 27, after forming the separation material layer 390 filling the third separation openings 970, the method further includes removing the fourth protective layer 370, the fifth mask layer 380, and portions of the separation material layer 390 higher than the second spacer material layer 800.

Referring to FIG. 28, the second spacer material layer 800 on the tops of the second core layers 220, the third core layers 230, and the base 100 is removed. The second spacer material layer 800 on sidewalls of the second core layers 220 and the third core layers 230 is retained as the second spacers 810. The second spacer material layer 800 below the third separation material layer 390 in the trenches 950 surrounded by the second spacer material layer 800 is retained, which forms the third separation structures 960.

In some embodiments, a dry etch process is used to remove the second spacer material layer 800 on the tops of the second core layers 220, the third core layers 230, and the base 100.

The dry etch process is an anisotropic etch process. Therefore, selecting the dry etch process helps minimize damage to the second core layers 220 and the third core layers 230. Additionally, dry etching is more directional, which helps improve the sidewall morphology quality and dimensional accuracy of the second spacers 810.

In some embodiments, removing of the second spacer material layer 800 on tops of the second core layers 220, the third core layers 230, and the base 100 exposes the tops of the second core layers 220 and the third core layers 230.

In some embodiments, in the step of removing the second spacer material layer 800 on the tops of the second core layers 220, and the third core layers 230, and the base 100, portions of the separation material layer 390 higher than the tops of the second core layers 220 and the third core layers 230 are also removed. The separation material layer 390 in the third separation openings 970 is retained as the third separation structures 960, which is used for subsequent pattern transfer to the target material layer 170.

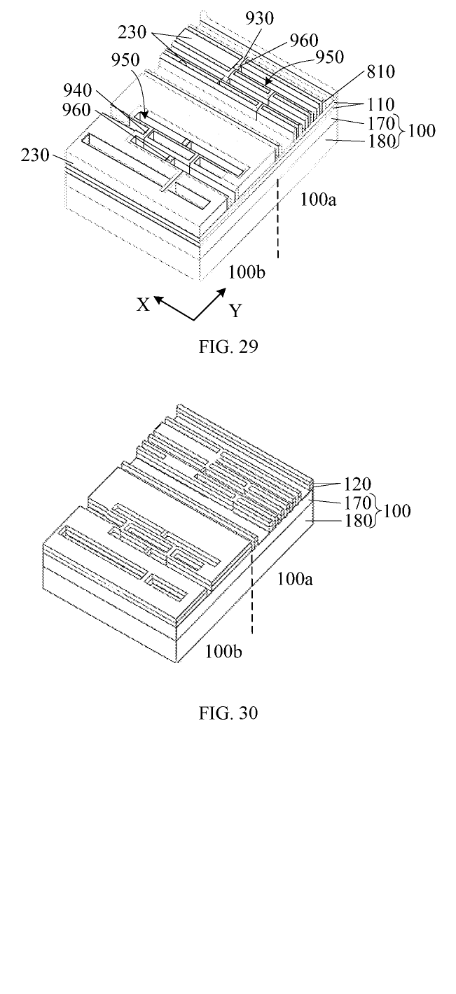

Referring to FIG. 29, the second core layers 220 are removed.

Removing the second core layers 220 prepares for subsequently patterning the target material layer 170 in the first area 100a and the second area 100b using the second spacers 810 and the third core layers 230 as a mask.

In some embodiments, a wet etch process is used to remove the second core layers 220.

The wet etch process has isotropic etching characteristics, which facilitates complete removal of the second core layers 220. Moreover, the wet etch process has relatively low cost, simple operation steps, and may achieve high etch selectivity. This helps minimize damage to the second spacers 810 during removal of the second core layers 220.

In some embodiments, in the step of removing the second core layers 220 using the wet etch process, the etch solution for the wet etch process includes one or more of KOH solution, THMA solution, and SC1 solution.

In some embodiments, the second core layers 220 are undoped silicon material, while the third core layers 230 are doped silicon material. KOH solution or THMA solution can achieve a high etch rate for undoped silicon while having almost no etch rate for doped silicon (especially doped with B ions). Therefore, using KOH solution or THMA solution as the etch solution enables complete removal of the second core layers 220 while minimizing damage to the third core layers 230. Additionally, alkaline solutions such as KOH solution, SC1 solution, and THMA solution have almost no etch rate for the third separation structures 960 formed by the separation material layer 390 and the second spacers 810. This ensures that the process of removing the second core layers 220 has almost no impact on other components during the entire pattern transfer process.

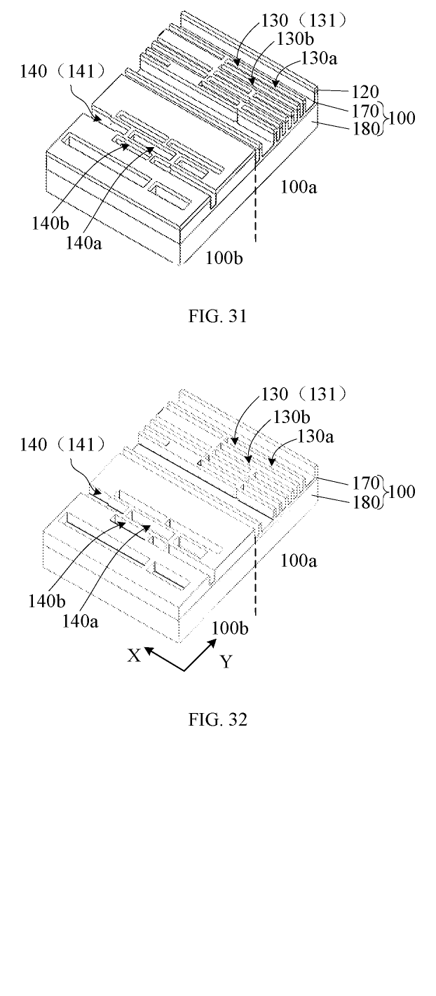

With reference to FIGS. 30 and 31, the target material layer 170 is patterned using the second spacers 810 and the third core layers 230 as a mask. First target structures 131 in the first area 100a and second target structures 141 in the second area 100b are formed.

Optionally, the target material layer 170 is patterned using the second spacers 810, the third core layers 230, the first separation structures 930, the second separation structures 940, and the third separation structures 960 as a mask. The first target structures 131 in the first area 100a and the second target structures 141 in the second area 100b are formed.

In some embodiments, for the first area 100a, the first spacers 510 covering sidewalls of the first core layers 410 are formed. The second core material layer 200 in the first area 100a is patterned using the first spacers 510 as a mask. The separate second core layers 220 in the first area 100a are formed. The second spacers 810 covering sidewalls of the second core layers 220 are formed. The target material layer 170 is patterned using the second spacers 810 as a mask, which adopts an SAQP process. The SAQP process may form first target structures 131 with a smaller pitch. For the second area 100b, a modification treatment is performed on certain portions of the second core material layer 200 in the second area 100b to transform the portions of the second core material layer 200 into the third core material layer 210 having an etch selectivity with the second core material layer 200. The second core material layer 200 and the third core material layer 210 in the second area 100b are patterned using the second protective layers 710. The second core layers 220 corresponding to the second core material layer 200 and the third core layers 230 corresponding to the third core material layer 210 are formed. The second spacers 810 covering sidewalls of the second core layers 220 and the third core layers 230 are formed. The target material layer 170 is patterned using the second spacers 810 and the third core layers 230 as a mask, which adopts an SALELE process to form the second target structures 141 with a larger pitch. That is, the SAQP process and the SALELE process may be effectively integrated, enabling the formation of both the first target structures 131 with a smaller pitch and the second target structures 141 with a larger pitch over the same base 100. This facilitates meeting more semiconductor process requirements through process integration and improves design freedom in patterning processes.

Optionally, in some embodiments, in the step of patterning the target material layer 170 using the second spacers 810 and the third core layers 230 as a mask and forming the first target structures 131 in the first area 100a and the second target structures 141 in the second area 100b, the target material layer 170 is also patterned using the first separation structures 930 and the second separation structures 940 as a mask. This results in portions of the target material layer 170 corresponding to the first separation structures 930 that separate the first target structures 131 along the first direction, and portions of the target material layer 170 corresponding to the second separation structures 940 that separate the second target structures 141 along the first direction.

In some embodiments, in the step of patterning the target material layer 170 using the second spacers 810 and the third core layers 230 as masks and forming the first target structures 131 in the first area 100a and the second target structures 141 in the second area 100b, the target material layer 170 is also patterned using the third separation structures 960 as a mask. This results in portions of the target material layer 170 corresponding to the third separation structures 960 that separate the first target structures 131 and the second target structures 141 along the first direction.

In some embodiments, in the step of patterning the target material layer 170 using the second spacers 810 and the third core layers 230 as a mask and forming the first target structures 131 in the first area 100a and the second target structures 141 in the second area 100b, portions of the target material layer 170 transferred from the third core layers 230 in the first area 100a may separate the first target structures 131 along the first direction and also reduce the formation of first target structures 131 along the first direction. This allows for the simultaneous elimination of unwanted first target structures 131 during pattern transfer to form the first target structures 131, making the process simple and efficient.

In some embodiments, in the step of patterning the target material layer 170 using the second spacers 810 and the third core layers 230 as a mask, a dielectric layer is patterned using the second spacers 810 and the third core layers 230 as a mask and the first trenches 130 and second trenches 140 in the dielectric layer are formed.

The first trenches 130 provide spatial positions for subsequently forming first metal lines, and the second trenches 140 provide spatial positions for subsequently forming second metal lines.

The first trenches 130 may be divided into type A first trenches 130a and type B first trenches 130b arranged at intervals. The type A first trenches 130a are first trenches 130 corresponding to the second core layers 220. The type B first trenches 130b are first trenches 130 corresponding to the trenches 950 surrounded by the second spacer material layer 800 of the second core layers 220.

In some embodiments, the target material layer 170 retained through transfer from the third core layers 230 corresponding to the first openings 620 is used to eliminate unnecessary type A first trenches 130a. The target material layer 170 retained through transfer from the third core layers 230 corresponding to the second openings 630 is used to eliminate unnecessary type B first trenches 130b.

The second trenches 140 may also be divided into type A second trenches 140a and type B second trenches 140b. The type A second trenches 140a are second trenches 140 corresponding to the second core layers 220. The type B second trenches 140b are second trenches 140 corresponding to the trenches 950 surrounded by the second spacer material layer 800 on sidewalls of the second core layers 220 and the third core layers 230.

Correspondingly, in some embodiments, portions of the dielectric layer corresponding to the first separation structures 930 separate the type A first trenches 130a along the first direction. Portions of the dielectric layer corresponding to the second separation structures 940 separate the type A second trenches 140a along the first direction. Portions of the dielectric layer corresponding to the third separation structures 960 separate the type B first trenches 130b and the type B second trenches 140b along the first direction.

Optionally, referring to FIG. 30, the step of patterning the target material layer 170 using the second spacers 810 and the third core layers 230 as a mask includes patterning the mask material layer 110 using the second spacers 810 and the third core layers 230 as a mask and forming a pattern transfer layer 120.

The second pattern transfer layer 120 is used as an etch mask for patterning the target material layer 170.

In some embodiments, after forming the second pattern transfer layer 120 and before subsequently patterning the target material layer 170 using the second pattern transfer layer 120 as a mask, the method further includes removing the second spacers 810 and the third core layers 230 to prepare for subsequently patterning the target material layer 170 using the second pattern transfer layer 120 as a mask.

Referring to FIG. 31, the target material layer 170 is patterned using the second pattern transfer layer 120 as a mask.

Patterns of the second spacers 810 and the third core layers 230 are transferred to the target material layer 170 through the second pattern transfer layer 120. It helps improve pattern transfer accuracy, resulting in higher dimensional accuracy for the first target structures 131 and the second target structures 141.

Optionally, an etch process is used to pattern the target material layer 170 using the second pattern transfer layer 120 as a mask. The second pattern transfer layer 120 is thinned during the step of patterning the target material layer 170. For example, the silicon oxide layer in the second pattern transfer layer 120 may be removed.

Referring to FIG. 32, after forming the first target structures 131 and the second target structures 141, the method further includes removing the second pattern transfer layer 120.

Removing the second pattern transfer layer 120 prepares for subsequent formation of the first metal lines and the second metal lines.

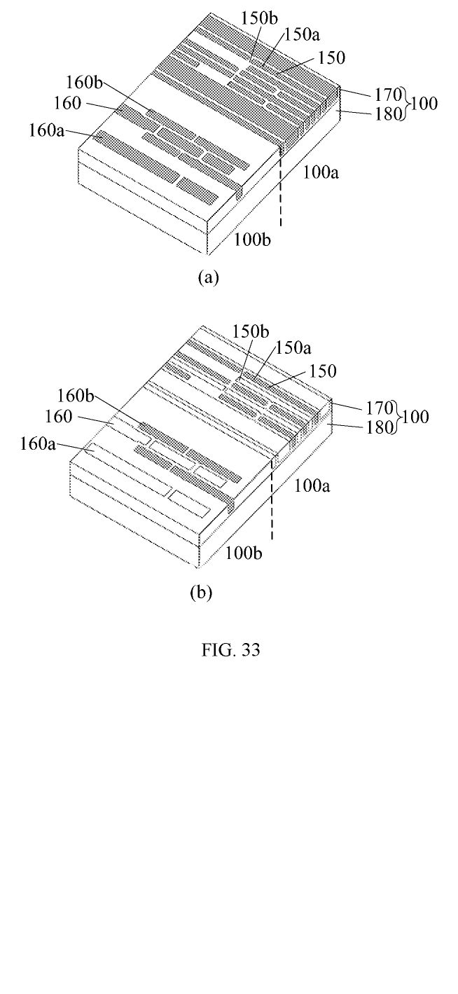

With reference to FIG. 33, after forming the first target structure 131 in the first area 100a and the second target structure 141 in the second area 100b, the method further includes forming first metal lines 150 in the first trenches 130 and forming second metal lines 160 in the second trenches 140.

The first metal lines 150 and the second metal lines 160 are metal interconnects in a back-end-of-line (BEOL) process.

Optionally, the dielectric layer transferred from the third core layers 230 in the first area 100a may separate the first metal lines 150 in the first trenches 130 along a first direction. The design freedom of the first metal line 150 in the first direction is achieved. Moreover, during the transfer of patterns to form the first metal lines 150, patterns are not transferred at positions where the first metal lines 150 are not required in the dielectric layer. Without adding masks and process steps, certain redundant first metal lines 150 in the first area 100a are removed. It reduces the capacitance among some of the first metal lines 150 in the first area 100a that are made through the SAQP process, thereby improving the performance of the circuit and chip of the semiconductor structure (e.g., better standard cell (STC) performance). The process is simple and efficient. Therefore, it enables the efficient and low-cost formation of the target structure as shown in part (a) of FIG. 35.

Part (b) of FIG. 33 schematically distinguishes between different types of the first metal lines 150 and the second metal lines 160 shown at part (a) of in FIG. 33.

Optionally, the first metal lines 150 may be divided into type A first metal lines 150a (as shown by the black-filled first metal lines 150 in the first area 100a of part (b) in FIG. 33) and type B first metal lines 150b (as shown by the white-filled first metal lines 150 in the first area 100a of part (b) in FIG. 33), which are arranged separately from each other. The type A first metal lines 150a are metal lines corresponding to the second core layer 220. The type B first metal lines 150b are metal lines corresponding to the trenches 950 surrounded by the second spacer material layer 800 of the second core layer 220.

In some embodiments, the dielectric layer retained by transfer of the third core layer 230 corresponding to the first openings 620 is used to eliminate unnecessary type A first metal lines 150a. The dielectric layer retained by transfer of the third core layer 230 corresponding to the second openings 630 is used to eliminate unnecessary type B first metal lines 150a.

Similarly, the second metal lines may also be divided into type A second metal lines 160a (as shown by the white-filled second metal lines 160 in the second area 100b of part (b) in FIG. 33) and type B second metal lines 160b (as shown by the black-filled second metal lines 160 in the second area 100b of part (b) in FIG. 33). The type A second metal lines 160a are metal lines corresponding to the second core layer 220. The type B second metal lines 160b are metal lines corresponding to the trenches 950 surrounded by the second spacer material layer 800 on sidewalls of the second core layer 220 and the third core layer 230. The type A second metal lines 160a and the type B second metal lines 160b may be arranged separately from each other, and the width, length, and pitch between them may be adjusted, offering greater design freedom compared to the first metal lines 150.

Correspondingly, in some embodiments, the dielectric layer corresponding to the first separation structures 930 separates the type-A first metal lines 150a along the first direction. The dielectric layer corresponding to the second separation structures 940 separates the type-A second metal lines 160a along the first direction. The dielectric layer corresponding to the third separation structures 960 separates the type-B first metal lines 150b and type-B second metal lines 160b along the first direction.

A dielectric layer is an inter metal dielectric (IMD) layer. The dielectric layer is used to achieve electrical isolation between metal interconnect lines in a BEOL process.

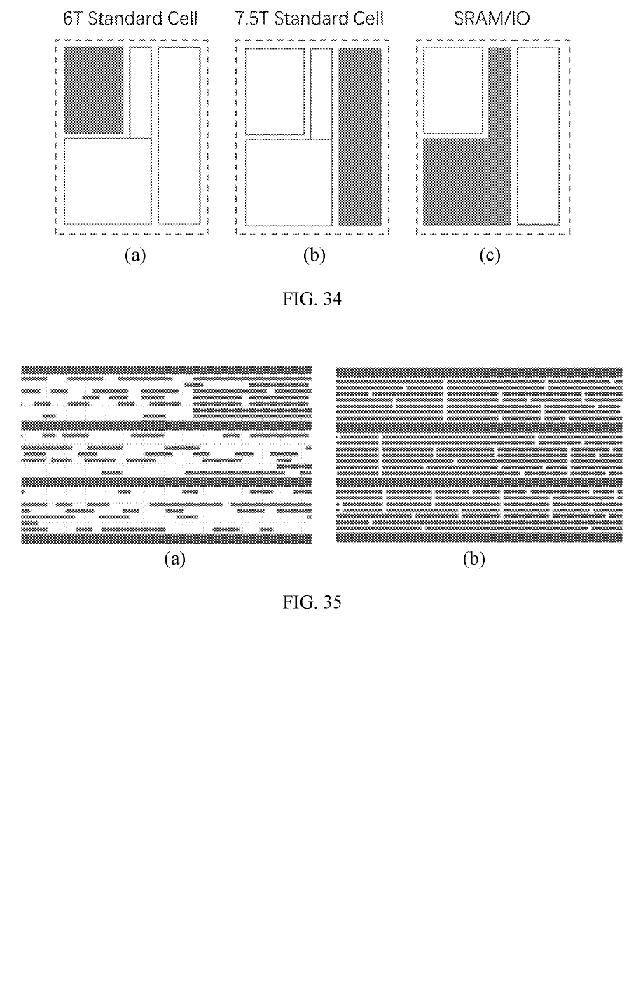

Exemplarily, as shown in FIG. 34, formation methods for some embodiments are illustrated. A 6T standard cell area, a 7.5T standard cell area, and an SRAM/input-output area (SRAM/IO) are formed over the base. The black area marks a corresponding device area.

Optionally, in the 6T standard cell area at part (a) of FIG. 34, the metal pitch reaches about 30 nm, and uniform metal lines for routing and wider power rails are required. Thus, SAQP may be used in the formation process. In the 7.5T standard cell area at part (b) of FIG. 34, the metal pitch is around 40 nm, and uniform metal lines for routing and wider power rails are required. Thus, SALELE may be used in the formation process. In the SRAM/IO area at part (c) of FIG. 34, the metal pitch is larger than 50 nm, and there are no clear layout rules for metal routing. Thus, SALELE may be used in the formation process. Therefore, by combining SAQP and SALELE, the 6T standard cell areas, 7.5T standard cell areas, and SRAM/IO areas that have different pitch requirements may be achieved over the same base.

Although the present disclosure is illustrated as above, the present disclosure is not limited thereto. Any person skilled in the art may make various changes and modifications without departing from the spirit and scope of the present disclosure. Therefore, the protection scope of the present disclosure should be subject to the scope defined by the claims.

What is claimed is:

1. A method for forming a semiconductor structure, comprising:
providing a base, wherein the base comprises a substrate and a target material layer on the substrate, a second core material layer is formed over the base, the base further comprises a first area for forming a plurality of first target structures and a second area for forming a plurality of second target structures, both the first target structure and the second target structure extend along a first direction, and a pitch between adjacent first target structures is smaller than or equal to a pitch between adjacent second target structures;
forming a plurality of first protective layers on the second core material layer, wherein a part of the plurality of first protective layers in the second area are separately disposed;
performing a modification treatment on the second core material layer exposed in the second area using the plurality of first protective layers as a mask and forming a third core material layer having an etch selectivity with respect to a remaining portion of the second core material layer, wherein the remaining portion of the second core material layer is separate in the second area and surrounded by the third core material layer in the second area;
removing the plurality of first protective layers;
forming a first core material layer covering the second core material layer and the third core material layer;
patterning the first core material layer and forming a plurality of first core layers being separate in the first area, wherein the plurality of first core layers extend along the first direction and are arranged parallel to each other along a second direction, the first direction is perpendicular to the second direction;
forming a plurality of first spacers covering sidewalls of the plurality of first core layers;
removing the plurality of first core layers;
forming a second protective layer on the second core material layer and the third core material layer in the second area, wherein a plurality of second protective layer openings are formed in the second protective layer, the plurality of second protective layer openings are separate, extend along the first direction, and are arranged parallel to each other along the second direction, and the plurality of second protective layer openings expose the third core material layer;
patterning the second core material layer and the third core material layer using the plurality of first spacers and the second protective layer as a mask and forming a plurality of second core layers corresponding to the second core material layer and a plurality of third core layers corresponding to the third core material layer;
removing the plurality of first spacers and the second protective layer;
forming a plurality of second spacers covering sidewalls of the plurality of second core layers and the plurality of third core layers;
removing the plurality of second core layers; and
patterning the target material layer using the plurality of second spacers and the plurality of third core layers as a mask and forming the plurality of first target structures in the first area and the plurality of second target structures in the second area.

2. The method according to claim 1, wherein in a step of providing the base, the target material layer is a dielectric layer, the plurality of first target structures are a plurality of first trenches, and the plurality of second target structures are a plurality of second trenches;
wherein in the step of patterning the target material layer using the plurality of second spacers and the plurality of third core layers as a mask, the dielectric layer is patterned using the plurality of second spacers and the plurality of third core layers as a mask and the plurality of first trenches and the plurality of second trenches are formed in the dielectric layer; and
wherein after forming the plurality of first target structures in the first area and the plurality of second target structures in the second area, the method further comprises forming a plurality of first metal lines in the plurality of first trenches and forming a plurality of second metal lines in the plurality of second trenches.

3. The method according to claim 1, wherein in a step of providing the base, the first area comprises a logic device area, and the second area comprises a peripheral device area.

4. The method according to claim 3, wherein a thickness of a gate oxide layer in the logic device area is smaller than a thickness of a gate oxide layer in the peripheral device area.

5. The method according to claim 1, wherein a minimum pitch between adjacent first target structures is 24 nm to 38 nm, and a minimum pitch between adjacent second target structures is 38 nm to 200 nm.

6. The method according to claim 1, wherein in a step of forming the plurality of first protective layers on the second core material layer, the plurality of first protective layers cover the second core material layer in the first area; or
wherein in a step of forming the plurality of first protective layers on the second core material layer, a first opening exposing the second core material layer is formed in the plurality of first protective layers in the first area, and the first opening extends along the first direction;
wherein in a step of performing the modification treatment on the second core material layer exposed in the second area using the plurality of first protective layers as a mask, the modification treatment is further performed on the second core material layer exposed by the first opening in the first area and the third core material layer in the first area is formed; and
wherein in a step of patterning the second core material layer and the third core material layer using the plurality of first spacers and the second protective layer as a mask, the third core material layer in the first area is further patterned using the plurality of first spacers to form the plurality of third core layers, and in the first area, the plurality of second core layers and the plurality of third core layers corresponding to portions of the plurality of first spacers are alternately distributed along the first direction.

7. The method according to claim 1, wherein in a step of forming the plurality of first protective layers on the second core material layer, the plurality of first protective layers cover the second core material layer in the first area; or
wherein in a step of forming the plurality of first protective layers on the second core material layer, a second opening exposing the second core material layer is formed in the plurality of first protective layers in the first area, and the second opening extends along the first direction;
wherein in a step of performing the modification treatment on the second core material layer exposed in the second area using the plurality of first protective layers as a mask, the modification treatment is further performed on the second core material layer exposed by the second opening in the first area and the third core material layer located in the first area is formed;
wherein in a step of forming the second protective layer on the second core material layer and the third core material layer in the second area, the second protective layer is also formed on the third core material layer in the first area; and
wherein in a step of patterning the second core material layer and the third core material layer using the plurality of first spacers and the second protective layer as a mask, the third core material layer located under the second protective layer in the first area is retained as the plurality of third core layers.

8. The method according to claim 1, wherein in a step of performing the modification treatment on the second core material layer exposed in the second area using the plurality of first protective layers as a mask, an ion implantation treatment is performed on the second core material layer exposed in the second area using the plurality of first protective layers as a mask and the third core material layer having an etch selectivity with respect to the second core material layer is formed.

9. The method according to claim 8, wherein in a step of providing the base, a material of the second core material layer comprises one or more of amorphous silicon, polysilicon, single crystal silicon, silicon oxide, advanced patterning film material, spin-on carbon, and silicon carbide; and
wherein in a step of performing the ion implantation treatment on the second core material layer exposed in the second area using the plurality of first protective layers as a mask, ions implanted in the ion implantation treatment comprise one or more of boron, phosphorus, arsenic, boron chloride, dichloroborane, and carbon.

10. The method according to claim 1, wherein in a step of performing the modification treatment on the second core material layer exposed in the second area using the plurality of first protective layers as a mask, the remaining portion of the second core material layer has a dimension of 35 nm to 200 nm along the second direction is and a pitch of 76 nm to 200 nm, and the third core material layer has a dimension of 35 nm to 200 nm along the second direction and a pitch of 76 nm to 200 nm.

11. The method according to claim 1, wherein a step of patterning the first core material layer comprises forming the plurality of first mask layers that are separate and on the first core material layer in the first area;
wherein the first core material layer is patterned through the plurality of first mask layers and the plurality of first core layers that are separate in the first area are formed; and
wherein after forming the plurality of first core layers, the method further comprises removing the plurality of first mask layers.

12. The method according to claim 1, wherein a step of forming the plurality of first spacers covering the sidewalls of the plurality of first core layers comprises:
forming a first spacer material layer covering tops and the sidewalls of the plurality of first core layers, and above the second core material layer and the third core material layer; and
removing portions of the first spacer material layer on the tops of the plurality of first core layers and above the second core material layer and the third core material layer, and retaining portions of the first spacer material layer on the sidewalls of the plurality of first core layers as the plurality of first spacers.

13. The method according to claim 1, wherein a step of forming the plurality of second spacers covering the sidewalls of the plurality of second core layers and the plurality of third core layers comprises:
forming a second spacer material layer covering the sidewalls and tops of the plurality of second core layers and the plurality of third core layers and a top of the base; and
removing portions of the second spacer material layer on the tops of the plurality of second core layers, the plurality of third core layers, and the base, and retaining portions of the second spacer material layer on the sidewalls of the plurality of second core layers and the plurality of third core layers as the plurality of second spacers.

14. The method according to claim 1, wherein before forming the first core material layer covering the second core material layer and the third core material layer, the method further comprises forming an etch stop layer covering the second core material layer and the third core material layer;
wherein in a step of forming the first core material layer covering the second core material layer and the third core material layer, the first core material layer covers the etch stop layer;
wherein before forming the second protective layer on the second core material layer in the second area, the method further comprises patterning the etch stop layer using the plurality of first spacers as a mask and forming a first pattern transfer layer;
wherein in a step of patterning the second core material layer and the third core material layer using the plurality of first spacers and the second protective layer as a mask, the second core material layer in the first area is patterned using the first pattern transfer layer as a mask, and the plurality of second core layers are formed that are separate in the first area; and
wherein after forming the plurality of second core layers and the plurality of third core layers, the method further comprises removing the first pattern transfer layer.

15. The method according to claim 1, wherein the plurality of second core layers are removed using a wet etching process, and an etching solution of the wet etching process comprises one or more of a KOH solution, a THMA solution, and an SC1 solution.

16. The method according to claim 1, wherein in a step of providing the base, a mask material layer is formed between the target material layer and the second core material layer;
wherein a step of patterning the target material layer using the plurality of second spacers and the plurality of third core layers as a mask comprises patterning the mask material layer using the plurality of second spacers and the plurality of third core layers as a mask and forming a second pattern transfer layer;
wherein the target material layer is patterned using the second pattern transfer layer as a mask; and
wherein after forming the plurality of first target structures and the plurality of second target structures, the method further comprises removing the second pattern transfer layer.

17. The method according to claim 16, wherein after forming the second pattern transfer layer and before patterning the target material layer using the second pattern transfer layer as a mask, the method further comprises removing the plurality of second spacers and the plurality of third core layers.

18. The method according to claim 1, wherein in a step of forming the first core material layer covering the second core material layer and the third core material layer, a material of the first core material layer comprises one or more of amorphous silicon, polysilicon, single crystal silicon, silicon oxide, advanced patterning film material, spin-on carbon, and silicon carbide.

19. The method according to claim 1, wherein after removing the second protective layer and before forming the plurality of second spacers covering the sidewalls of the plurality of second core layers and the plurality of third core layers, the method further comprises patterning a portion of the plurality of second core layers in the first area and portions of the plurality of second core layers and the plurality of third core layers in the second area, and forming a plurality of first separation openings separating the plurality of second core layers in the first area along the first direction and a plurality of second separation openings separating the plurality of second core layers in the second area along the first direction;
wherein in a step of forming the plurality of second spacers covering the sidewalls of the plurality of second core layers and the plurality of third core layers, the plurality of second spacers further cover sidewalls of the first separation openings and sidewalls of the plurality of second separation openings, the plurality of second spacers on opposite sidewalls of the plurality of first separation openings contact each other to form a plurality of first separation structures, and the plurality of second spacers on opposite sidewalls of the plurality of second separation openings contact each other to form a plurality of second separation structures; and
wherein in a step of patterning the target material layer using the plurality of second spacers and the plurality of third core layers as a mask and forming the plurality of first target structures in the first area and the plurality of second target structures in the second area, the target material layer is further patterned using the plurality of first separation structures and the plurality of second separation structures as a mask, portions of the target material layer corresponding to the plurality of first separation structures separate the plurality of first target structures along the first direction, and portions of the target material layer corresponding to the plurality of second separation structures separate the plurality of second target structures along the first direction.

20. The method according to claim 13, wherein in a step of forming the second spacer material layer covering the sidewalls and tops of the plurality of second core layers and the plurality of third core layers and the top of the base, the second spacer material layer on opposite sidewalls surrounds and forms a plurality of trenches;
wherein after forming the second spacer material layer covering the sidewalls and tops of the plurality of second core layers and the plurality of third core layers and the top of the base, and before removing the second spacer material layer on the tops of the second core layers, the third core layers, and the base, the method further comprises forming a plurality of third separation structures extending along the second direction in the plurality of trenches in the first area and the second area and contacting the plurality of second spacers, and the plurality of third separation structures separate the plurality of trenches along the first direction; and
wherein in a step of patterning the target material layer using the plurality of second spacers and the plurality of third core layers as a mask and forming the plurality of first target structures in the first area and the plurality of second target structures in the second area, the target material layer is further patterned using the plurality of third separation structures as a mask, and portions of the target material layer corresponding to the plurality of third separation structures separate the plurality of first target structures and the plurality of second target structures along the first direction.
